(19) United States
(12) Patent Application Publication
(10) Pub. No.: US 2025/0370837 A1
(43) Pub. Date: Dec. 4, 2025

(54) DATA DECODING DEVICE, ERROR CORRECTION SYSTEM, AND NON-TRANSITORY COMPUTER-READABLE MEDIUM STORING A DATA DECODING PROGRAM

(71) Applicant: FANUC CORPORATION, Minamitsuru-gun, Yamanashi (JP)

(72) Inventor: Daijirou KOGA, Yamanashi (JP)

(73) Assignee: FANUC CORPORATION, Minamitsuru-gun, Yamanashi (JP)

(21) Appl. No.: 18/873,239

(22) PCT Filed: Jun. 24, 2022
(86) PCT No.: PCT/JP2022/025416

§ 371 Date: Dec. 9, 2024

(51) Int. Cl. G06F 11/07

(52) U.S. Cl. CPC G06F 11/076; G06F 11/0736; G06F 11/0793

(57) ABSTRACT

Provided is a data decoding technique that enables decoding of post-encoding axis-dependent data obtained by encoding axis-dependent data that depends on the coordinate value of each axis of an industrial machine. A data decoding device 1 comprises a decoding unit 11 that generates post-model approximation decoding axis-dependent data which is obtained by decoding model approximation encoded axis-dependent data on the basis of: a linear combination model that approximates axis-dependent data that depends on the coordinate value of each axis of an industrial machine, as a linear combination of respective axis data of the industrial machine; and post-model approximation encoding axis-dependent data which is obtained by model approximation by the linear combination model.

### TECHNICAL FIELD

The present disclosure relates to a data decoding device, an error compensation system, and a data decoding program.

### BACKGROUND ART

Conventionally, industrial machines such as a machine tool and a robot each cause a predetermined control point to move to a predetermined position in accordance with a command value. However, since such industrial machines are subject to error, the position of the control point often does not conform to the command value. In order to resolve such a decrease in positioning accuracy which would lead to a decrease in machining accuracy, a technique has been proposed which compensates for an error so that the position of a control point conforms to a command value (for example, refer to Patent Document 1). With this technique, by inputting the error amount measured in advance to a control device, the error is compensated based on the compensation amount corresponding to the error amount.

### CITATION LIST

### Patent Document

Patent Document 1: Japanese Unexamined Patent Application, Publication No. 2011-209897

### DISCLOSURE OF THE INVENTION

### Problems to be Solved by the Invention

By the way, upon compensating for the error, as the number of input points of the error amount inputted to the control device increases, the error can be compensated with higher accuracy. However, since there is an upper limit to the inputtable data size, there is a problem in that the accuracy of error compensation cannot be improved beyond the upper limit of the inputtable data size.

Therefore, it is conceivable to compress the data of the error amount and input the compressed data to the control device. Examples of a technique for compressing data include a data encoding technique, and for example, an entropy encoding technique such as Huffman coding is known. The entropy encoding technique compresses data by utilizing bias in the appearance frequency of values on the data, i.e., the smallness of information entropy.

However, the axis-dependent data depending on the coordinate values of each axis of an industrial machine such as the above-described error amount may have a white noise-like property in which the appearance frequency is uniform as a whole. In this case, since the above-described smallness of information entropy cannot be used, it is difficult to compress data by the entropy encoding technique.

Therefore, the inventor of the present invention has studied a data encoding technique capable of encoding and compressing axis-dependent data depending on coordinate values of each axis of an industrial machine. An object of the present disclosure is to provide a data decoding technique capable of decoding encoded axis-dependent data obtained by encoding axis-dependent data depending on coordinate values of each axis of an industrial machine.

### Means for Solving the Problems

An aspect of the present disclosure is directed to a data decoding device that decodes encoded data, including: a decoder that generates, based on a linear combination model that approximates axis-dependent data depending on coordinate values of each axis of an industrial machine as a linear combination of data of each axis of the industrial machine, and model approximation encoded axis-dependent data that are model-approximated by the linear combination model, model approximation decoded axis-dependent data obtained by decoding the model approximation encoded axis-dependent data.

Another aspect of the present disclosure is directed to an error compensation system that compensates for an error of an industrial machine, the system including a compensator and the data decoding device according to the above aspect, in which the compensator compensates for the error of the industrial machine based on the decoded axis-dependent data.

Yet another aspect of the present disclosure is directed to a data decoding program that decodes encoded data, and the program causes a computer to execute a step of generating, based on a linear combination model that approximates axis-dependent data depending on coordinate values of each axis of an industrial machine as a linear combination of data of each axis of the industrial machine and model approximation encoded axis-dependent data that are model-approximated by the linear combination model, model approximation decoded axis-dependent data obtained by decoding the model approximation encoded axis-dependent data.

### Effects of the Invention

According to the present disclosure, it is possible to provide a data decoding technique capable of decoding encoded axis-dependent data obtained by encoding axis-dependent data depending on coordinate values of each axis of an industrial machine.

### BRIEF DESCRIPTION OF THE DRAWINGS

FIG. 1 is a diagram showing a configuration of a data decoding device according to a first embodiment;

FIG. 2 is a diagram showing a configuration of a first example of a data encoding device;

FIG. 3 is a diagram showing an example of a text file including only specific characters;

FIG. 4 is a diagram showing an example of data in which the appearance frequency of each value is represented by a specific distribution;

FIG. 5 is a diagram showing data in which the appearance frequency of each value is uniform;

FIG. 6 is a diagram showing each axis error of the X-axis error;

FIG. 7 is a diagram showing each axis error of the Y axis;

FIG. 8 is a diagram showing error amounts at coordinate values (X₂, Y₁);

FIG. 9 is a diagram showing error amounts which cannot be expressed with a linear combination of each axis error;

FIG. 10 is a partially enlarged view of FIG. 8;

FIG. 11 is a diagram showing a bitmap image in which an error map is visualized;

FIG. 12 is a diagram showing an example of axis-dependent data;

FIG. 13 is a diagram showing a linear combination model approximating the axis-dependent data of FIG. 12 as a linear combination of each axis error of an industrial machine;

FIG. 14 is a diagram showing a configuration of a second example of the data encoding device;

FIG. 15 is a diagram showing axis-dependent data divided into a plurality of grid regions;

FIG. 16 is a diagram showing an example of divided axis-dependent data;

FIG. 17 is a diagram showing a configuration of a third example of the data encoding device;

FIG. 18 is a flowchart showing a procedure of dividing axis-dependent data by a dynamic programming processor;

FIG. 19 is a diagram showing a divided section before expanding data of each axis (each axis error) by one row in the X positive direction;

FIG. 20 is a diagram showing a divided section after expanding data of each axis (each axis error) by one row in the X positive direction;

FIG. 21 is a diagram showing a configuration of a fourth example of the data encoding device;

FIG. 22 is a diagram showing approximation errors (vectors Y [X] [Y]);

FIG. 23 is a diagram showing a configuration of a fifth example of the data encoding device;

FIG. 24 is a diagram showing approximation errors (vectors Y [X] [Y]) including exception points larger than a predetermined tolerance;

FIG. 25 is a diagram showing exception points that are excluded and held due to being larger than a predetermined tolerance in the approximation errors (vectors γ [X] [Y]);

FIG. 26 is a diagram showing a configuration of a sixth example of the data encoding device;

FIG. 27 is a diagram showing a configuration of a seventh example of the data encoding device;

FIG. 28 is a flowchart showing a procedure of learning processing by a machine learning device;

FIG. 29 is a diagram showing a configuration of a data decoding device according to a second embodiment;

FIG. 30 is a diagram showing a configuration of a data decoding device according to a third embodiment;

FIG. 31 is a diagram showing a configuration of an error compensation system including the data decoding device according to the first embodiment; and

FIG. 32 is a diagram for explaining error compensation by a compensator.

### PREFERRED MODE FOR CARRYING OUT THE INVENTION

Hereinafter, embodiments of the present disclosure will be described in detail with reference to the drawings. In the description of the second and subsequent embodiments, the description of the configuration common to the first embodiment will be omitted as appropriate.

### FIRST EMBODIMENT

Axis-dependent data such as error amounts for use in error compensation of each axis of an industrial machine may have a white noise-like property with a uniform appearance frequency as a whole. Therefore, it is difficult to compress the axis-dependent data in the conventional entropy encoding technique using the bias of the appearance frequency of the values on the data, that is, the smallness of the information entropy. On the contrary, a data decoding device 1 according to the present embodiment is a data decoding device capable of decoding data obtained by encoding and compressing the axis-dependent data depending on coordinate values of each axis of an industrial machine.

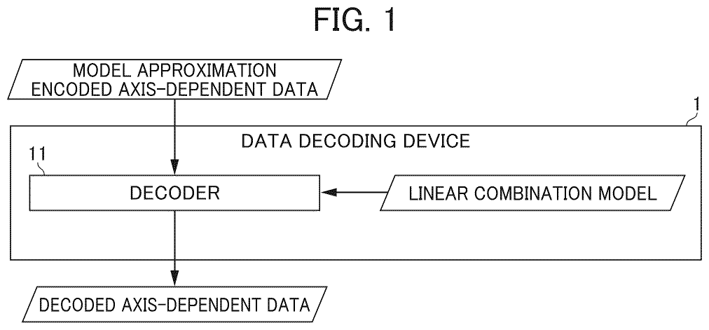

FIG. 1 is a diagram showing a configuration of a data decoding device 1 according to a first embodiment. As shown in FIG. 1, the data decoding device 1 includes a decoder 11. The decoder 11 generates model approximation decoded axis-dependent data as decoded axis-dependent data based on model approximation encoded axis-dependent data and a linear combination model.

### <Data Encoding Device>

First, before describing the configuration of the data decoding device 1, a data encoding device capable of encoding and compressing axis-dependent data depending on coordinate values of each axis of an industrial machine will be described in detail together with a conventional data encoding technique.

### FIRST EXAMPLE

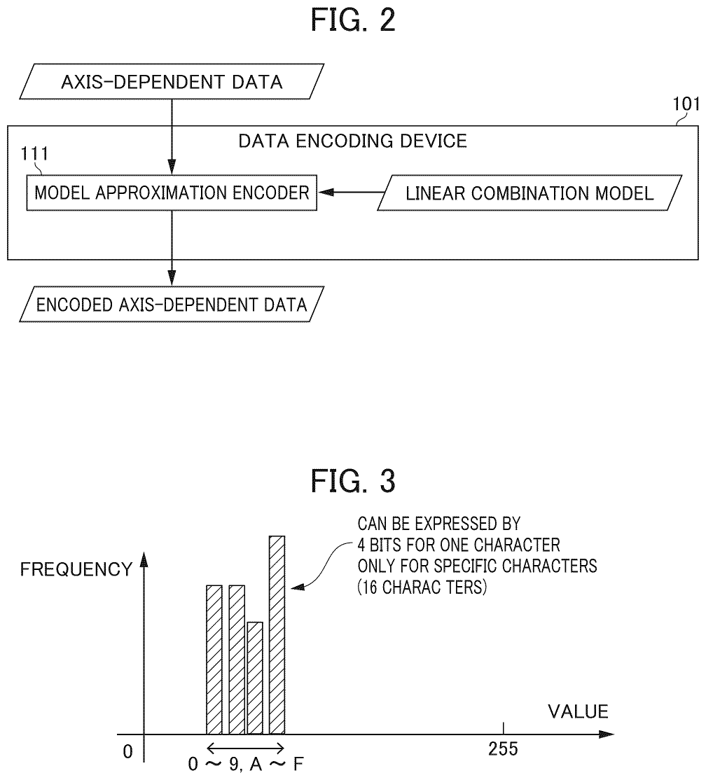

FIG. 2 is a diagram showing a configuration of a first example of a data encoding device. As shown in FIG. 2, the data encoding device 101 includes a model approximation encoder 111. The model approximation encoder 111 generates model approximation encoded axis-dependent data (hereinafter also referred to as encoded axis-dependent data) by encoding the axis-dependent data based on the axis-dependent data and the linear combination model.

As a data encoding technique, for example, an entropy encoding technique such as Huffman coding is conventionally known. The entropy encoding technique compresses data by utilizing bias in the appearance frequency of values on the data, i.e., the smallness of information entropy.

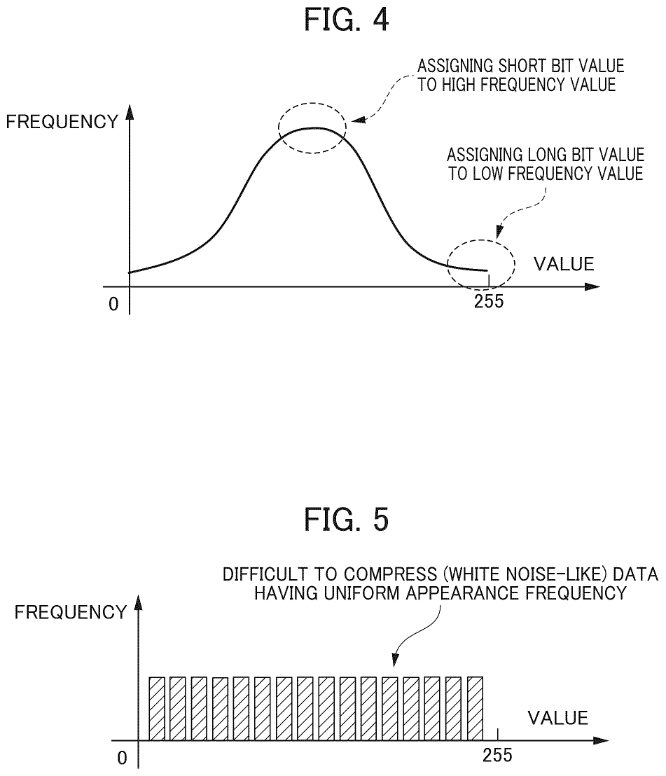

Herein, FIG. 3 is a diagram showing an example of a text file including only specific characters. Further, FIG. 4 is a diagram showing an example of data in which the appearance frequency of each value is represented by a specific distribution. In each of FIGS. 3 and 4, the horizontal axis indicates a bit value, and the vertical axis indicates an appearance frequency of each value. As shown in FIG. 3, for example, a text file including only 16 characters of 0 to 9 and A to F as specific characters normally requires 8 bits for expression of one character, but can be expressed by 4 bits at most for expression of one character by entropy encoding, so that data can be compressed in about half. Further, data having a non-uniform appearance frequency as shown in FIG. 4 can be compressed by assigning a short bit value to a high frequency value and assigning a long bit value to a low frequency value by entropy encoding.

On the other hand, FIG. 5 is a diagram showing data in which the appearance frequency of each value is uniform. Similarly to FIGS. 3 and 4, in FIG. 5, the horizontal axis indicates a bit value, and the vertical axis indicates the appearance frequency of each value. Since white noise-like data having a uniform appearance frequency as shown in FIG. 5 cannot utilize the above-described smallness of information entropy, it is difficult to compress the data by entropy encoding.

By the way, examples of the static error compensation of each axis of the industrial machine include pitch error compensation, straightness error compensation, and three-dimensional error compensation. The pitch error compensation is compensation of an error in a direction along the axial direction. The straightness error compensation is compensation of an error in a direction orthogonal to the axial direction. The three-dimensional error compensation is compensation of a three-dimensional spatial error. These error compensations are executed by inputting the amount of error (hereinafter, referred to as each axis error) measured for each coordinate value of each axis to the control device for the number of axes. As the number of input points increases, the accuracy of error compensation improves, but there is an upper limit to the size of data that can be inputted.

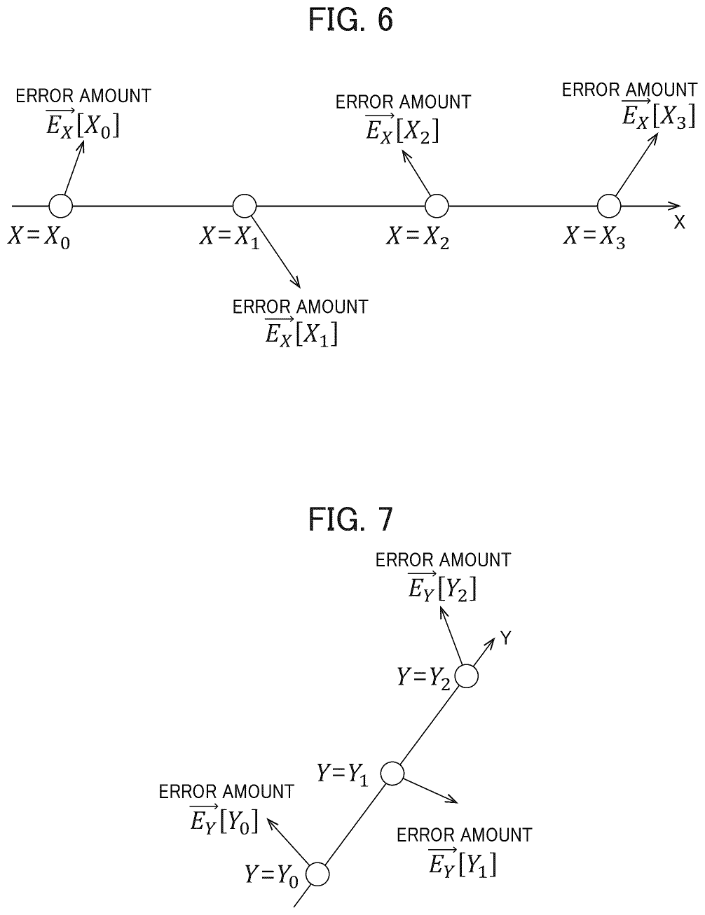

FIG. 6 is a diagram showing each axis error of the X-axis. Each axis error of the X axis is an error amount of each coordinate value measured when only the X axis is moved in a state where the Y axis and the Z axis are fixed. As shown in FIG. 6, the error amounts of the coordinate values X₀, X₁, X₂, and Xa are displayed as vectors having different sizes and directions.

FIG. 7 is a diagram showing each axis error of the Y axis. Each axis error of the Y axis is an error amount of each coordinate value measured when only the Y axis is moved in a state where the X axis and the Z axis are fixed. As shown in FIG. 7, the error amounts of the coordinate values Y₀, Y₁, and Y₂ are displayed as vectors having different sizes and directions.

Here, in the error compensation of each axis, it is assumed that each axis error is linearly independent. That is, assuming that the error amount in each of the coordinate values X₁ . . . . X_{L} (vector E[X¹] . . . [X^{L}]) is a linear combination of each axis error, the error amount is expressed by the following expression (1).

$$[ Expression 1 ]$$

$$\vec{E} [ {X}^{- 1} ] … [ {X}^{L} ] := {\sum }_{l = 1}^{L} \vec{{E}_{{X}^{l}}} [ {X}^{l} ] \qquad Expression ( 1 )$$

In Expression (1) above, L represents the number of target axes subjected to error compensation. Further, X¹ represents the first compensation target axis.

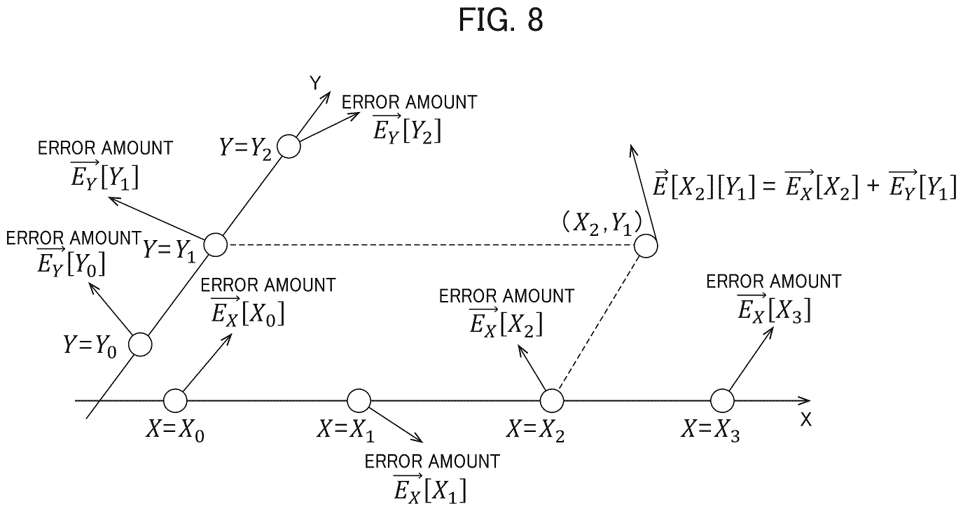

There are many situations where the above expression (1) based on the above assumption holds, and conventionally, error compensation for each axis is widely used. For example, FIG. 8 is a diagram showing an error amount in the coordinate value (X₂, Y₁). As shown in FIG. 8, the error amount (vector E[X₂] [Y₁]) in the coordinate value (X₂, Y₁) can be regarded as a linear combination of the error amount (vector E_{X} [X₂]) in the coordinate value X₂ and the error amount (vector E_{Y}[Y₁]) in the coordinate value Y₁, and is represented by the following expression (2).

$$[ Expression 2 ]$$

$$\vec{E} [ {X}_{2} ] [ {Y}_{1} ] = \vec{{E}_{X}} [ {X}_{2} ] + \vec{{E}_{Y}} [ {X}_{1} ] \qquad Expression ( 2 )$$

However, when viewed as a whole, the appearance frequency of the value in each axis error (vector E_{X} [X], vector E_{X} [Y]) or the appearance frequency of the value in the error amount (vector E [X] [Y]) may be uniform in a white noise-like manner. In this case, it is difficult to compress the data by the conventional entropy encoding technique using the bias of the appearance frequency of the values on the data, that is, the smallness of information entropy.

In addition, each axis error may not be linearly independent, or the error amount (vector E [X¹] . . . [X^{L}]) may be determined by correlation between a plurality of axes. That is, the error amount (vector E[X¹] . . . [X^{L}]) includes the correlation term (vector δ[X¹] . . . [X^{L}]) as represented by the following expression (3), and may not be represented by a linear combination of each axis error.

$$[ Expression 3 ]$$

$$\vec{E} [ {X}^{1} ] … [ {X}^{L} ] := {\sum }_{l = 1}^{L} \vec{{E}_{{X}^{l}}} [ {X}^{l} ] + \vec{δ} [ {X}^{1} ] … [ {X}^{L} ] \qquad Expression ( 3 )$$

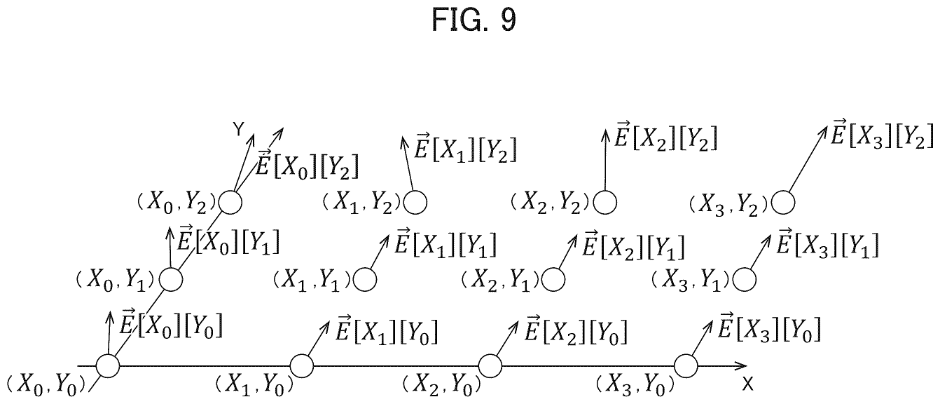

FIG. 9 is a diagram showing error amounts which cannot be expressed with a linear combination of each axis error. As shown in FIG. 9, when each axis error is not linear independent, the error amount (vector E [X¹] . . . [X^{L}]) needs to be an error amount including a correlation term (vector δ[X¹] . . . [X^{L}]) represented by the above-described expression (3), instead of the error amount represented by the above-described expression (1). In this case, since the error amount (hereinafter, referred to as a spatial error) is inputted to a control device and compensated for each space having a correlation with the error amount, it is called error compensation for each space.

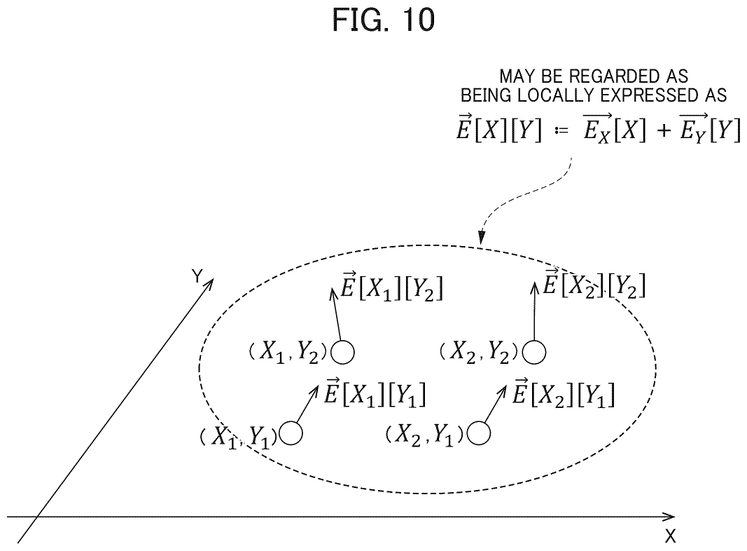

Here, the present inventor has found that the spatial error cannot be expressed as a linear combination of each axis error as a whole, but can be locally regarded as a linear combination of each axis error as in the case of each axis error. For example, FIG. 10 is a partial enlarged view of FIG. 9. However, in the local region surrounded by the broken line in FIG. 10, the above correlation term (vector δ[X¹] . . . [X^{L}]) can be regarded as 0, and the spatial error can be represented as a linear combination of each axis error. That is, the spatial error (vector E[X] [Y]) is represented by the sum of each axis error (vector E_{X} [X]) and each axis error (vector E_{Y}[Y]) as shown in the following expression (4). This indicates that the spatial error (vector E [X] [Y]) can be approximated as a linear combination of an error amount (vector E_{X}[X]) in one row in the X-axis direction and an error amount (vector E_{Y}[Y]) in one row in the Y-axis direction, among data of each axis (each axis error) on a plurality of coordinate points in a grid manner. It should be noted that the examples of the local region include a central region of a movable range of the industrial machine.

$$[ Expression 4 ]$$

$$\vec{E} [ X ] [ Y ] := \vec{{E}_{X}} [ X ] + \vec{{E}_{Y}} [ Y ] \qquad Expression ( 4 )$$

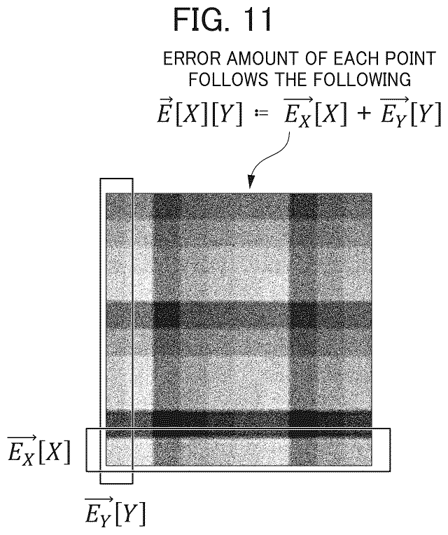

However, when viewed as a whole, the appearance frequency of values in the spatial error (vector E[X] [Y]) may be uniform in a white noise-like manner, and thus it is difficult to compress the data by a conventional entropy encoding technique using the smallness of information entropy. For example, FIG. 11 is a diagram showing a bitmap image visualizing an error map in a case where the target axes of error compensation are two axes of the X axis and the Y axis, and RGB values of each pixel correspond to the error amount vector E. Further, the error amount (vector E [X] [Y]) of each pixel is represented by the sum of the vector E_{X}[X] and the vector E_{Y}[Y] in accordance with Expression (4). For example, in a case where the number of pixels of the bitmap image shown in FIG. 11 is 10×10 and 374 bytes, when the bitmap image is encoded by ZIP compression, which is a typical entropy encoding technique, 393 bytes are obtained. As described above, it can be seen that the conventionally known entropy encoding has no compression effect, and in some cases, the data size increases, resulting in an inverse effect.

In view of the above, in the data encoding device 101, even for axis-dependent data depending on coordinate values of each axis of an industrial machine such as an error amount or the like for use in error compensation of each axis of the industrial machine, the property is utilized which can be locally regarded as a linear combination of each axis error as represented by the above-described expression (1). As a result, it is possible for the data encoding device 101 to encode and compress the axis-dependent data, which has been difficult in the related art.

Referring back to FIG. 2, the data encoding device 101 includes a computer including, for example, memory such as ROM (read only memory) and RAM (random access memory), a CPU (control processing unit), an operation unit such as a keyboard, a display, and a communication controller, which are connected to each other via a bus. The functions and operations of the functional units described later are achieved by the cooperation of the CPU and memory which are mounted on the computer, and control programs stored in the memory.

The data encoding device 101 may be provided in, for example, a numerical control device (CNC: Computerized Numerical Control) or a robot control device corresponding to a control device of a machine tool or an industrial machine such as a robot. Alternatively, the data encoding device 101 may be provided in an external computer or the like so as to be able to communicate with these control devices.

The model approximation encoder 111 included in the data encoding device 101 generates encoded axis-dependent data obtained by encoding the axis-dependent data based on a portion of the axis-dependent data depending on coordinate values of each axis of the industrial machine and a linear combination model that approximates the axis-dependent data as a linear combination of data of each axis (each axis error) of the industrial machine. The axis-dependent data is inputted from, for example, the above-described control device or the like. Further, the linear combination model is stored in, for example, the storage of the data encoding device 101.

Here, each axis of the industrial machine indicates, for example, each axis of the machine tool, that is, the X axis, the Y axis, and the Z axis. Further, examples of the axis-dependent data include the error amount for use in the error compensation of each axis of the industrial machine and, for example, an installation error amount of a relatively large workpiece whose displacement is different for each coordinate value due to the influence of deflection due to its own weight. Each of the error amount and the installation error amount of the workpiece is data depending on coordinate values of each axis of the industrial machine.

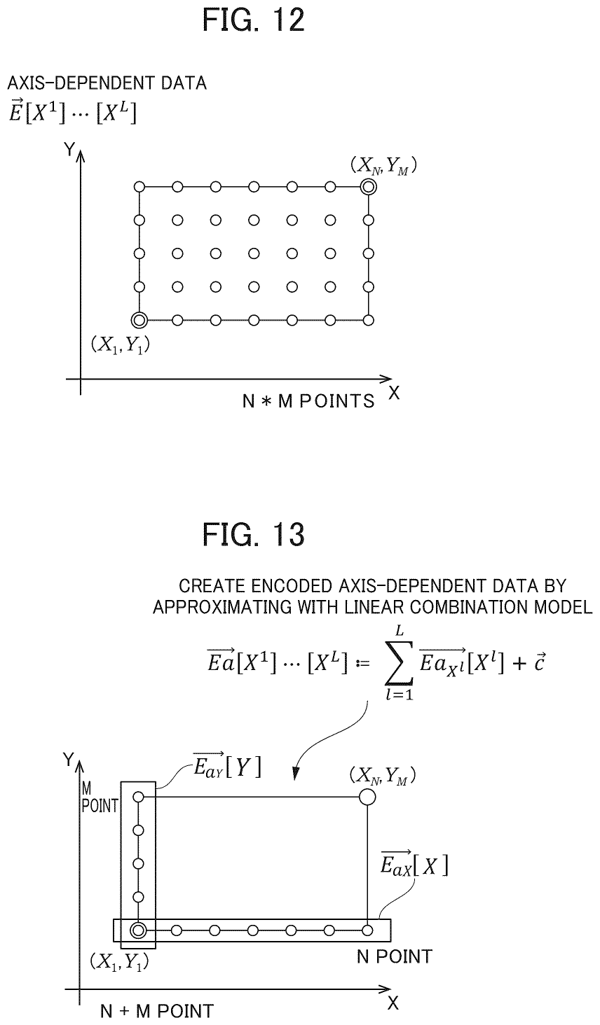

Hereinafter, the model approximation encoding using a linear combination model by the model approximation encoder 111 will be described in detail with reference to FIGS. 12 and 13.

FIG. 12 is a diagram showing an example of axis-dependent data. In the example shown in FIG. 12, axis-dependent data in a case where two axes, i.e., the X-axis and the Y-axis, are used as target axes for error compensation and the like is shown. The axis-dependent data shown in FIG. 12 is axis-dependent data of a specific local region in axis-dependent data in which there is no bias in the appearance frequency of values on the data as a whole in terms of, for example, error amounts of each axis of the industrial machine, and is axis-dependent data that can be approximated by a linear combination model described later. The example of the axis-dependent data shown in FIG. 12 includes data of each axis (each axis error) of N×M points in total.

FIG. 13 is a diagram showing a linear combination model approximating the axis-dependent data of FIG. 12 as a linear combination of each axis error of an industrial machine. As described above, even when the error amount (vector E [X¹] . . . [X]) conforms to the model represented by Expression (3) and the influence of the correlation term (vector δ[X¹] . . . [X^{L}]) is considered to be strong as a whole, it is considered that a region that can be approximated by the linear combination model represented by the mathematical Expression (1) locally exists. For such a region that can be approximated, as shown in FIG. 13, the error amount can be expressed by an approximation model (vector Ea[X¹] . . . [X^{L}]) as a linear combination model represented by the following Expression (5). That is, the error amount can be approximated as a linear combination of an error amount (vector Ea_{X}[X]) in one row in the X-axis direction and an error amount (vector Ea_{Y}[Y]) in one row in the Y-axis direction. In the example shown in FIG. 13, data of each axis (each axis error) after approximation becomes N+M points in total, and it can be seen that the axis-dependent data can be compressed.

$$[ Expression 5 ]$$

$$\vec{Ea} [ {X}^{1} ] … [ {X}^{L} ] := {{\sum }^{L}}_{l = 1} \vec{{Ea}_{{X}^{l}}} [ {X}^{l} ] + \vec{c} \qquad Expression ( 5 )$$

In Expression (5), X₁ and X^{L} are represented by Expression (6) below, and a vector c is defined as an average value as represented by Expression (7) below. The vector Ea_{X}[X¹] is expressed by the following Expression (8). Further, L represents the number of target axes subjected to error compensation, X¹ represents the first compensation target axis, and N¹ represents the error amount point of the first compensation target axis.

$$[ Expression 6 ]$$

$${X}^{1} := [ {X}_{1}^{1} , … , {X}_{{N}^{1}}^{1} ] … {X}^{L} := [ {X}_{1}^{L} , … , {X}_{{N}^{L}}^{L} ] \qquad Expression ( 6 )$$

$$[ Expression 7 ]$$

$$\vec{c} := \frac{1}{{\sum }_{l = 1}^{L} {N}^{l}} {{\sum }^{{N}^{1}}}_{{X}^{1} = 1} … {{\sum }^{{N}^{L}}}_{{X}^{L} = 1} ( \vec{E} [ {X}^{1} ] … [ {X}^{L} ] - {{\sum }^{{N}^{L}}}_{{X}^{L} = 1} \vec{{Ea}_{{X}^{l}}} [ {X}^{l} ] … [ {x}^{L} ] ) \qquad Expression ( 7 )$$

$$[ Expression 8 ]$$

$$\begin{matrix}\vec{{Ea}_{{X}^{l}}} [ {X}^{l} ] := \vec{E} [ {x}^{1} ] … [ {X}^{l} ] \\ provided that {X}^{p} is any value that satisfies \\ ( {X}_{1}^{p} \leq {x}^{p} \leq {X}_{{N}^{p}}^{p} ) and common in each \vec{{Ea}_{{X}^{l}}} [ {X}^{l} ]\end{matrix} \qquad Expression 8$$

In Expression (8), while X represents a one-dimensional axial space, x represents an element belonging to the space. The symbol p is any value from 1 to L. For example, x³ indicates a certain value that can be taken by the axis x³.

When the vector c is defined as in the above Expression (7), the approximation model (vector Ea[X₁] . . . [X_{L}]) as the linear combination model becomes a maximum likelihood estimation model that minimizes the evaluation function J expressed by the following Expression (9). That is, the evaluation function J is expressed as the sum of squares of the difference between the original error amount before approximation (vector E [X¹] . . . [X^{L}]) and the error amount after approximation (vector Ea[X¹] . . . [X^{L}]), as represented by the following Expression (9), and the approximation model (vector Ea[X¹] . . . [X^{L}]) as the linear combination model is determined so that the evaluation function J is minimized. The approximation model as the linear combination model thus determined is stored in, for example, the storage of the data encoding device 101, and is used for model approximation encoding by the model approximation encoder 111.

$$[ Expression 9 ]$$

$$J := {{\sum }^{{N}^{1}}}_{{X1}^{= 1}} … {{\sum }^{{N}^{L}}}_{{X}^{L} = 1} ( \vec{E} [ {X}^{1} ] … [ {X}^{L} ] - \vec{Ea} [ {X}^{1} ] … [ {X}^{L} ] ) \cdot ( \vec{E} [ {X}^{1} ] … [ {X}^{L} ] - \vec{Ea} [ {X}^{1} ] … [ {X}^{L} ] ) \qquad Expression ( 9 )$$

As described above, according to the data encoding device 101, by approximating a portion of the axis-dependent data as a linear combination of data of each axis (each axis error), it is possible to encode and compress the axis-dependent data, which has been difficult to compress conventionally. In addition, according to the data encoding device 101, by using the encoded axis-dependent data that have been encoded and compressed, it is possible to increase data such as the error amount that can be inputted to the control device of the industrial machine or the like without increasing the storage capacity, and thus it is possible to compensate for the error of the industrial machine with higher accuracy.

### SECOND EXAMPLE

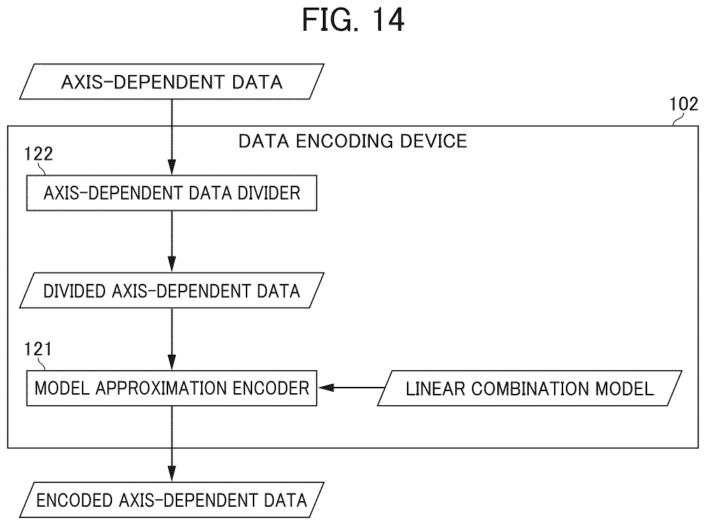

FIG. 14 is a diagram showing a configuration of a second example of the data encoding device. As shown in FIG. 14, the data encoding device 102 differs from the data encoding device 101 in that the data encoding device 102 includes an axis-dependent data divider 122. In addition, the model approximation encoder 121 differs from the model approximation encoder 111 of the first example described above in that the model approximation encoder performs the model approximation encoding based on divided axis-dependent data generated by dividing the axis-dependent data into a plurality of pieces of data and the linear combination model described above. The configuration other than these differences is the same as that of the first example.

The above-described data encoding device 101 performs model approximation encoding of a linear combination model on the assumption that a portion of axis-dependent data having a uniform appearance frequency in a white noise-like manner as a whole can be regarded as a linear combination of data of each axis (each axis error). On the other hand, the data encoding device 102 actively divides the axis-dependent data into a plurality of regions to generate a plurality of regions that can be regarded as the linear combination of data of each axis (each axis error), thereby enabling the execution of the model approximation encoding of the linear combination model more reliably.

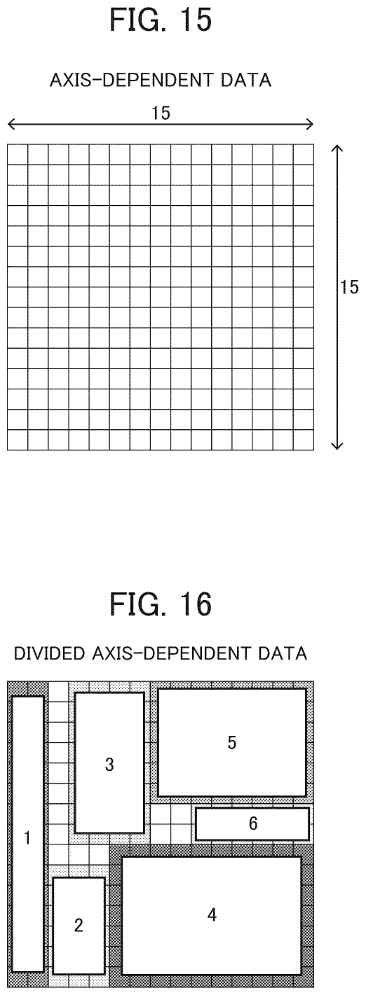

The axis-dependent data divider 122 divides the axis-dependent data to generate a plurality of divided axis-dependent data. Here, FIG. 15 is a diagram showing axis-dependent data divided into a plurality of grid regions. As shown in FIG. 15, the axis-dependent data inputted to the data encoding device 102 is divided into a plurality of grid regions according to data of each axis (each axis error) on each coordinate value, for example. In the example shown in FIG. 15, the axis-dependent data is divided into a grid of 15×15=225 points. The axis-dependent data divider 122 divides the axis-dependent data into a plurality of sections based on the grid, for example.

The method of dividing the axis-dependent data by the axis-dependent data divider 122 is not particularly limited, but it is preferable to divide the axis-dependent data so as to generate a plurality of regions that can be regarded as the linear combination of data of each axis (each axis error). In particular, it is preferable that the axis-dependent data divider 122 divides the axis-dependent data into a plurality of regions that can be best approximated (compressed).

FIG. 16 is a diagram showing an example of divided axis-dependent data. In the example shown in FIG. 16, the axis-dependent data inputted to the data encoding device 102 is divided into five sections 1 to 5 by the axis-dependent data divider 122. That is, the respective data in the respective regions of the five divided sections 1 to 5 correspond to the divided axis-dependent data, and each of the divided axis-dependent data can be regarded as a linear combination of data of each axis (each axis error), and the model approximation encoding of the linear combination model by the model approximation encoder 121 described later is possible. On the other hand, outside these five divided sections 1 to 5, the axis-dependent data cannot be regarded as a linear combination of data of each axis (each axis error), and model approximation encoding of the linear combination model is impossible.

The model approximation encoder 121 generates encoded axis-dependent data based on the plurality of divided axis-dependent data and the linear combination model. As described above, in each region of the plurality of divided sections 1 to 5, the axis-dependent data can be regarded as a linear combination of data of each axis (each axis error). Therefore, the model approximation encoder 121 performs model approximation encoding of the linear combination model on each of the divided axis-dependent data to generate the encoded axis-dependent data that are model-approximated and compressed.

As described above, according to the data encoding device 102, by actively dividing the axis-dependent data into a plurality of regions, it is possible to generate each of the plurality of regions that can be regarded as a linear combination of data of each axis (each axis error), and by performing the model approximation encoding of the linear combination model for each region, it is possible to more reliably compress the axis-dependent data, which has been difficult to compress conventionally.

### THIRD EXAMPLE

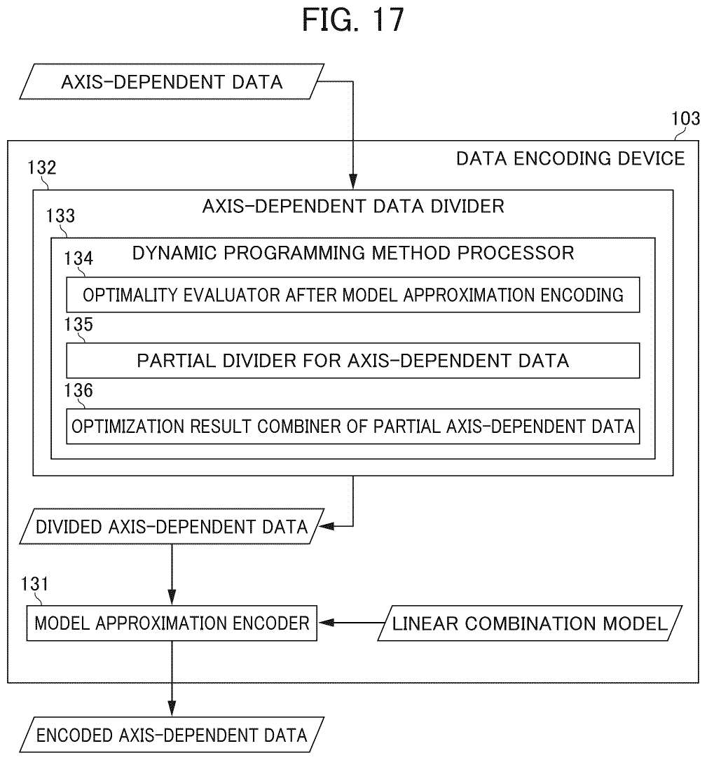

FIG. 17 is a diagram showing a configuration of a third example of the data encoding device. As shown in FIG. 17, a data encoding device 103 differs from the second example in that the configuration of an axis-dependent data divider 132 differs from that of the axis-dependent data divider 122 described above. The configurations other than this difference are the same as those of the second example.

In the above-described data encoding device 102, the method of dividing the axis-dependent data is not particularly limited, but in the data encoding device 103, the axis-dependent data is divided using a dynamic programming method. That is, by using the dynamic programming method, the optimal division of the axis-dependent data can be executed, and the axis-dependent data can be best approximated and compressed.

As shown in FIG. 17, the axis-dependent data divider 132 includes a dynamic programming processor 133. The dynamic programming processor 133 generates optimal divided axis-dependent data by executing the dynamic programming method. Specifically, the dynamic programming processor 133 includes, as functional units for executing the dynamic programming method, an optimality evaluator 134 after model approximation encoding, a partial divider 135 of the axis-dependent data, and an optimization result combiner 136 of the partial axis-dependent data.

Here, the dynamic programming method executed by the dynamic programming processor 133 will be described in detail.

The dynamic programming method is a generic algorithm for solving optimized problems. The dynamic programming method is an algorithm having the following two features. The first feature is to solve recursively. That is, the first feature is characterized in that a problem is divided into partial problems of a small scale, the partial problems are recursively optimized, and the optimization results of the partial problems are combined to obtain a solution of the original problem of a larger scale. The second feature is that the processing load can be reduced by recording the optimization results. That is, the second feature is characterized in that, although the same problems may appear many times in the process of recursively solving the problems, in order to omit the calculation of a problem which has been solved, the optimization result of the problem which has been solved once is recorded and reused.

Therefore, the dynamic programming processor 133 of the present embodiment includes an optimality evaluator 134 after model approximation encoding as a means for evaluating the optimality of the result. That is, the optimality evaluator 134 after the model approximation encoding evaluates the optimality of the encoded axis-dependent data. The evaluation of the optimality of the encoded axis-dependent data can be performed based on, for example, whether an approximation error amount after the model approximation encoding is within a predetermined constraint tolerance. In addition, as described in detail in a fourth example to be described later, the approximation error amount after the model approximation encoding is a difference between the original error amount before the model approximation encoding described in the above-described first example and the error amount after the model approximation encoding. The constraint tolerance may be, for example, an allowable approximation error value or an allowable number of points of data exceeding the allowable approximation error value.

In addition, the dynamic programming processor 133 includes the partial divider 135 of axis-dependent data as a means for dividing a problem into partial problems. The partial divider 135 of the axis-dependent data divides the axis-dependent data into a plurality of portions to generate partial axis-dependent data. For example, the partial divider 135 of the axis-dependent data divides the axis-dependent data into predetermined designated sections in accordance with a predetermined division criterion stored in advance, and reduces the resultant data by one point in each of the positive direction and the negative direction of each axis such as the X axis and the Y axis to optimize the resultant data, thereby obtaining a plurality of portions of the axis-dependent data. The division of the axis-dependent data by the partial divider 135 of the axis-dependent data will be described later in detail.

In addition, the dynamic programming processor 133 includes the optimization result combiner 136 for the partial axis-dependent data as a means for combining the optimization results of the partial problems. The optimization result combiner 136 for the partial axis-dependent data expands and combines the partial axis-dependent data to generate optimal divided axis-dependent data. The optimization result combiner 136 for the partial axis-dependent data optimizes the partial axis-dependent data generated by dividing the axis-dependent data by the partial divider 135 of the above-described axis-dependent data by expanding the partial axis-dependent data by one point in each of the positive direction and the negative direction of each axis such as the X axis and the Y axis. The generation of the optimal divided axis-dependent data by the optimization result combiner 136 for the partial axis-dependent data will be described later in detail.

Hereinafter, the division of the axis-dependent data by the dynamic programming processor 133 will be described in detail with reference to FIGS. 15, 16, 18, and 19.

As shown in FIG. 15, the axis-dependent data is divided into, for example, a grid of 15×15=225 points. When such axis-dependent data are divided into sections by the dynamic programming processor 133, for example, divided axis-dependent data as shown in FIG. 16 are obtained. In the division into sections of the axis-dependent data by the dynamic programming processor 133, an approximation error of each error amount in a case where each region of the divided sections is approximated by the above-described approximation model is set to fall within a constraint allowable amount. Further, each of the points at which the approximation error does not fall within the constraint allowable amount is allowed up to the constraint allowable number. Nevertheless, the points that cannot be approximated or do not meet the constraint are minimized in number. As a result, for example, the number of data points 225 can be compressed to 92 points, and the data size can be reduced.

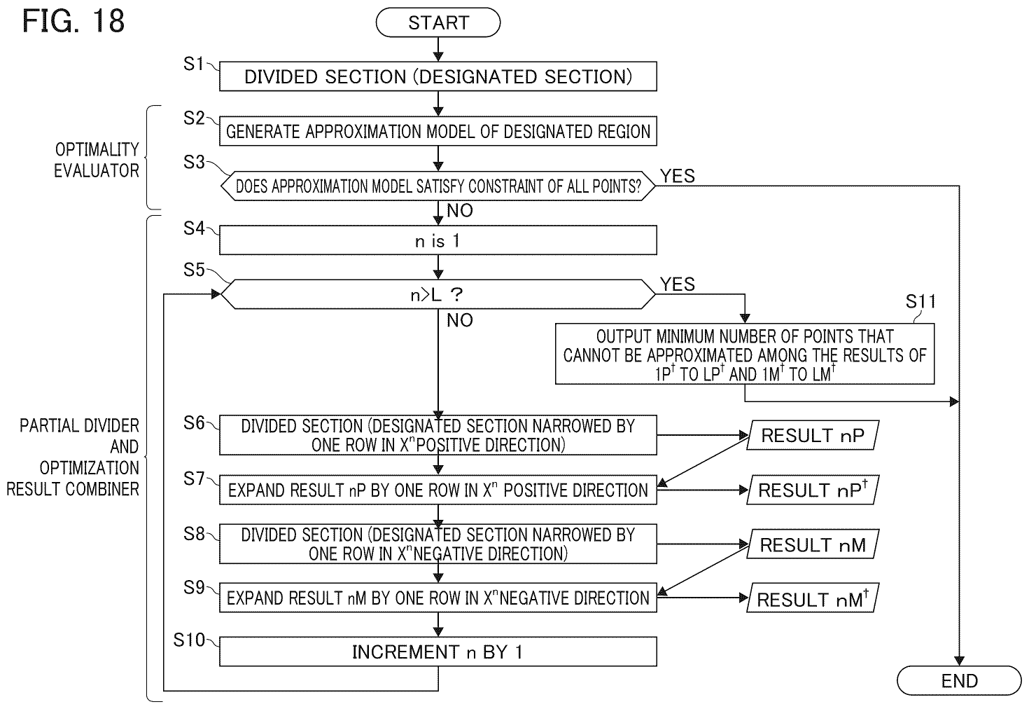

FIG. 18 is a flowchart showing a procedure of dividing the axis-dependent data by the dynamic programming processor 133. The division of the axis-dependent data by the dynamic programming processor 133 is executed by recursively searching for optimal divided sections of the axis-dependent data by the dynamic programming method.

In Step S1, the axis-dependent data is divided into predetermined designated sections. However, in a case of a region in which the division processing of the axis-dependent data has been performed by the dynamic programming processor 133, the held processing result may be reflected in this step. Thereafter, the processing proceeds to Step S2.

In Step S2, an approximation model of each of the regions of the designated sections (designated regions) divided in Step S1 is generated. Specifically, an approximation model (vectors Ea[X₁] . . . [X_{L}]) as a linear combination model described in the first embodiment is generated for each designated region. Thereafter, the processing proceeds to Step S3.

In Step S3, it is determined whether the approximation models of the designated regions generated in Step S2 satisfy the constraint of all points. Examples of the constraint include whether the approximation errors of all points are within the allowable value, and whether the number of points at which the approximation errors are not within the allowable value is within the allowable number of points. When it is determined as YES, it is determined that the axis-dependent data has been optimally divided and optimally divided axis-dependent data has been obtained, and the processing ends. On the other hand, when it is determined as NO, the processing proceeds to Step S4.

In Step S4, n is set to the initial value 1. Here, the value of n represents each axis and, for example, in a case where the axis configuration is a total of the two axes of the X axis and the Y axis, the value of n represents the X axis when n is 1, and the value of n represents the Y axis when n is 2. Thereafter, the processing proceeds to Step S5.

In Step S5, it is determined whether n is larger than L. Here, L is the number of axes in the designated section of the axis-dependent data. For example, in a case of the two axes of the X axis and the Y axis, L is 2. When it is determined as YES, the processing proceeds to Step S11. On the other hand, when it is determined as NO, the processing proceeds to Step S6.

The processing of Steps S6 to S10 is a case where n is equal to or less than L, and when the number of axes is the two axes of the X axis and the Y axis, and when n is 1, it indicates processing for the X axis, and when n is 2, it indicates processing for the Y axis.

In Step S6, the axis-dependent data is divided into designated sections in which data of each axis (each axis error) is narrowed by one row in the XD positive direction from the designated sections of Step S1. That is, a new divided section is executed in which data of each axis (each axis error) is reduced by one row in the Xⁿ positive direction. The Xª positive direction indicates the X-axis positive direction when n is 1. The result is outputted as an optimization result nP. When n is 1, the optimization result 1P is outputted. Thereafter, the processing proceeds to Step S7.

In Step S7, the optimization result nP obtained in Step S6 is expanded in the X″ positive direction by one row of data of each axis (each axis error). The result is outputted as an optimization result nP⁺. When n is 1, the optimization result 1P⁺is outputted. Since n can be in the range of 1 to L, the optimization results 1P to LP⁺ can be obtained by this step. Thereafter, the processing proceeds to Step S8.

In Step S8, the axis-dependent data is divided into designated sections in which the data of each axis (each axis error) is narrowed by one row in the X° negative direction from the designated sections in Step S1. That is, a new divided section is executed which is reduced by one row of data of each axis (each axis error) in the negative X″ direction. The X″ negative direction indicates the X-axis negative direction when n is 1. The result is outputted as an optimization result nM. When n is 1, the optimization result 1M is outputted. Thereafter, the processing proceeds to Step S9.

In Step S9, the optimization result nM obtained in Step S8 is expanded in the X″ negative direction by one row of data of each axis (each axis error). The result is outputted as an optimization result nM+. When n is 1, the optimization result 1M⁺is outputted. Since n can be in the range of 1 to L, this step results in optimization results 1M to LM+. Thereafter, the processing proceeds to Step S10.

In Step S10, n is incremented by 1. Thereafter, the processing returns to Step S5.

In addition, Step S11 is processing when n is larger than L, and when the number of axes is two axes, i.e., the X axis and the Y axis, Step S11 is performed after the processing for the X axis and the Y axis is completed in Steps S6 to S10. In Step S11, among the optimization results 1P to LP+ and 1M to LM⁺ obtained in Steps S6 to S10, those having the smallest number of points that cannot be approximated are outputted. That is, for each of the optimization results 1P to LP+ and 1M to LM⁺, the number of points that cannot be approximated for which the approximation model generated in Step S3 does not satisfy the above-described constraint is calculated, and those having the minimum number of points that cannot be approximated, approximated best, and compressed most are obtained, and then the processing is ended.

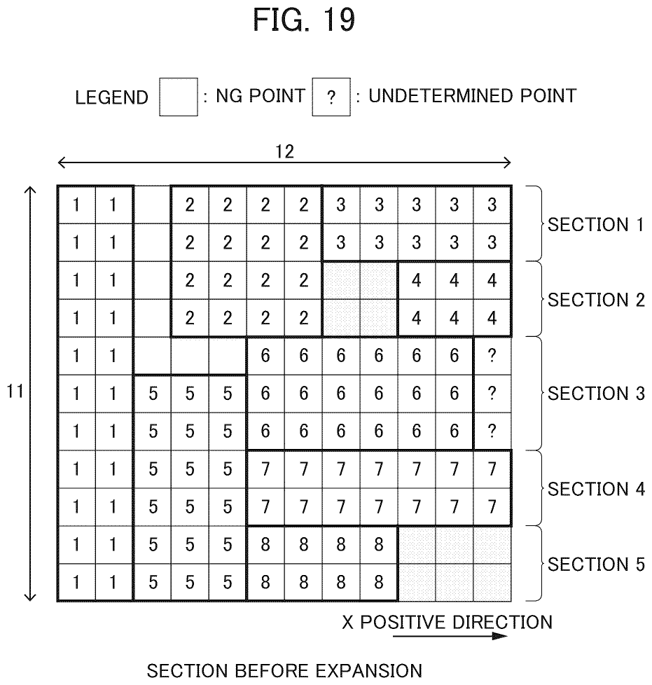

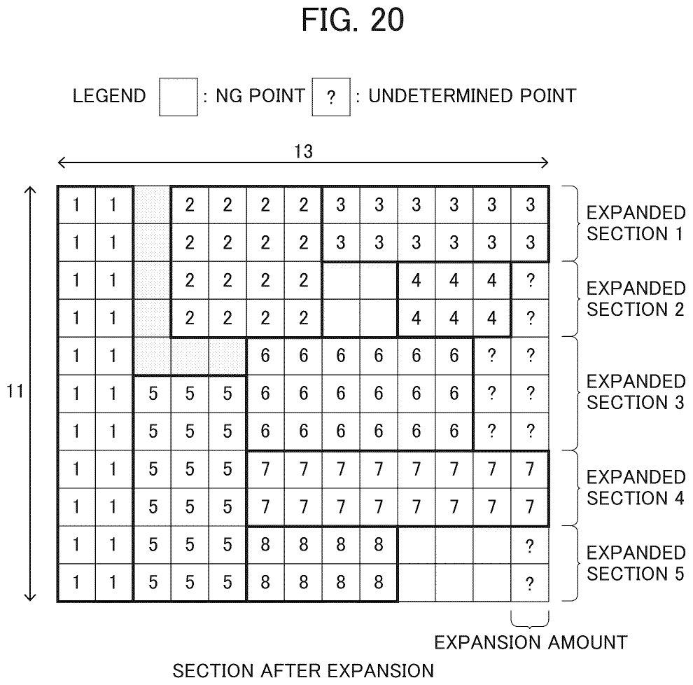

Here, the procedure of expanding one row of data of each axis (each axis error) in the X positive direction in the above-described Step S7 will be described in more detail with reference to specific examples shown in FIGS. 19 and 20. FIG. 19 is a diagram showing divided sections before expanding data of each axis (each axis error) by one row in the X positive direction. In addition, FIG. 20 is a diagram showing divided sections after expanding the data of each axis (each axis error) by one row in the X positive direction. In FIGS. 19 and 20, different numbers are assigned to the respective divided sections.

As shown in FIG. 19, first, sections 1 to 5 are extracted as continuous sections that appear at the end portion in the X positive direction of the sections before expansion by one row of data of each axis (each axis error).

Then, each of the extracted sections 1 to 5 is expanded by one row of data of each axis (each axis error) to generate expanded sections 1 to 5, as shown in FIG. 20.

Next, for each of the expanded sections 1 to 5, it is checked whether the above-described approximation model satisfies the above-described constraint. If the constraint is satisfied, the expanded sections are set as the new sections. In the example shown in FIG. 20, since the expanded sections 1 and 4 satisfy the constraint, they are set as new sections.

If the constraint is not satisfied, the sections of the expansion amount are set as undetermined sections. In the example shown in FIG. 20, since the expanded section 2 does not satisfy the constraint, it is set as an undetermined section.

When each of the undetermined sections is equal to or larger than a predetermined area (for example, 2× 2), it is checked whether the above-described approximation model satisfies the above-described constraint. In the example shown in FIG. 20, since the expanded section 3 is equal to or larger than a predetermined area (for example, 2×2), this determination is performed. Until then, this expanded section is also determined as an undetermined section.

In addition, in a case where the section before expansion is an NG section, that is, a section that does not satisfy the constraint and cannot be approximated, the section of the expansion amount is an undetermined section. In the example shown in FIG. 20, since the expanded section 5 corresponds to the NG section, it is set as an undetermined section.

As described above, there is a case where an undetermined section remains until the end. Such a section may finally be an NG section, that is, a section that does not satisfy the constraint and cannot be approximated.

As described above, according to the data encoding device 103, since the axis-dependent data can be divided into the optimal divided axis-dependent data that can be compressed while reducing the number of pieces of data to the most, it is possible to generate an optimal plurality of regions that can each be regarded as a linear combination of data of each axis (each axis error), and by executing the model approximation encoding of the linear combination model for each region, it is possible to further compress the axis-dependent data, which has been difficult to compress conventionally.

### FOURTH EXAMPLE

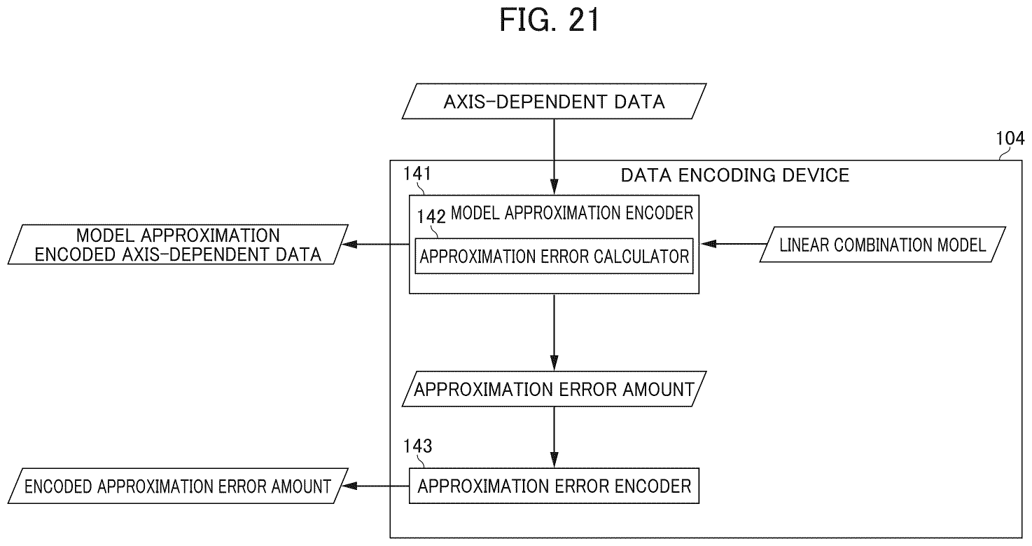

FIG. 21 is a diagram showing a configuration of a fourth example of the data encoding device. As shown in FIG. 21, the data encoding device 104 differs from the above-described model approximation encoder 111 in that a model approximation encoder 141 includes an approximation error calculator 142. The data encoding device 104 differs from the data encoding device 101 described above in that the data encoding device 104 includes an approximation error encoder 143. The configurations other than these differences are the same as those of the first example.

The approximation error calculator 142 calculates an approximation error amount. The approximation error calculator 142 is provided in the model approximation encoder 141, and calculates an approximation error amount in accordance with model approximation encoding of the axis-dependent data. This approximation error amount will be described later in detail.

The approximation error encoder 143 encodes the approximation error amount to generate an encoded approximation error amount. Since the approximation error amount calculated by the approximation error calculator 142 has a bias in the appearance frequency of values on data as described later and the information entropy is small in many cases, it is possible to encode the approximation error amount and compress the data by conventionally known entropy encoding. Alternatively, the data compression may be performed by performing the model approximation encoding of the linear combination model executed by the model approximation encoder 141.

Hereinafter, the approximation error amount and the encoding of the approximation error amount by the approximation error encoder 143 will be described in more detail.

As described in the above-mentioned first example, when the error amount is expressed by the approximation model (vector Ea[X¹] . . . [X^{L}]) as the linear combination model expressed by the above-described Expression (5), the approximation errors (vectors γ[X¹] . . . [XL]) are expressed by the following Expression (10).

$$[ Expression 10 ]$$

$$\vec{γ} [ {X}^{1} ] … [ {X}^{L} ] := \vec{E} [ {X}^{1} ] … [ {X}^{L} ] - \vec{Ea} [ {X}^{1} ] … [ {X}^{L} ] \qquad Expression ( 10 )$$

In Expression (10), vectors E [X¹] . . . [X^{L}] are original error amounts before model approximation, and vectors Ea[X¹] . . . [X^{L}] are error amounts after model approximation. It can be seen from Expression (10) that these differences are approximation errors (vectors γ[X¹] . . . [X^{L}]).

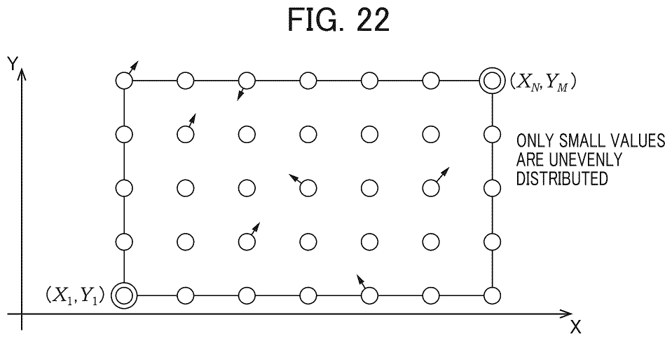

Here, since the approximation model (vector Ea[X¹] . . . [X^{L}]) is the maximum likelihood estimation model, the approximation errors (vectors γ[X¹] . . . [X^{L}]) are minimized and become only very small values. Here, FIG. 22 is a diagram showing approximation errors (vectors γ[X] [Y]). As shown in FIG. 22, only small values of the approximation errors (vectors γ[X] [Y]) are biased in value, and the frequency distribution of the values is also biased in frequency. Therefore, data can be compressed by encoding the approximation errors (vectors γ[X¹] . . . [X^{L}]).

When the approximation errors (vectors γ[X¹] . . . [X^{L}]) are encoded, the encoding method is not particularly limited. For example, the approximation errors (vectors γ[X¹] . . . [X^{L}]) may be encoded by the above-described model approximation encoding of the linear combination, or the approximation errors (vectors γ[X¹] . . . [X^{L}]) may be encoded by entropy encoding represented by conventionally known Huffman coding.

The approximation model (vector Ea[X¹] . . . [X^{L}]) alone differs from the original error amount (vector E[X¹] . . . [X^{L}]) by the approximation errors (vectors γ[X¹] . . . [X^{L}]). Further, since the approximation errors (vector γ[X¹] . . . [X^{L}]) exist according to the number of data of each axis, if the approximation errors are held as they are, it is not possible to compress the data. However, if the approximation errors (vectors γ[X¹] . . . [X^{L}]) are encoded and combined with the approximation model (vector Ea[X¹] . . . [X^{L}]), the original error amount (vector E[X¹] . . . [X^{L}]) can be compressed and reproduced without loss, and the total data size can also be reduced.

As described above, according to the data encoding device 104, it is possible to encode and compress the axis-dependent data, which has been difficult to compress conventionally, and to reproduce the axis-dependent data such as the original error amount without loss, while further reducing the total data size by encoding the approximation error amount.

### FIFTH EXAMPLE

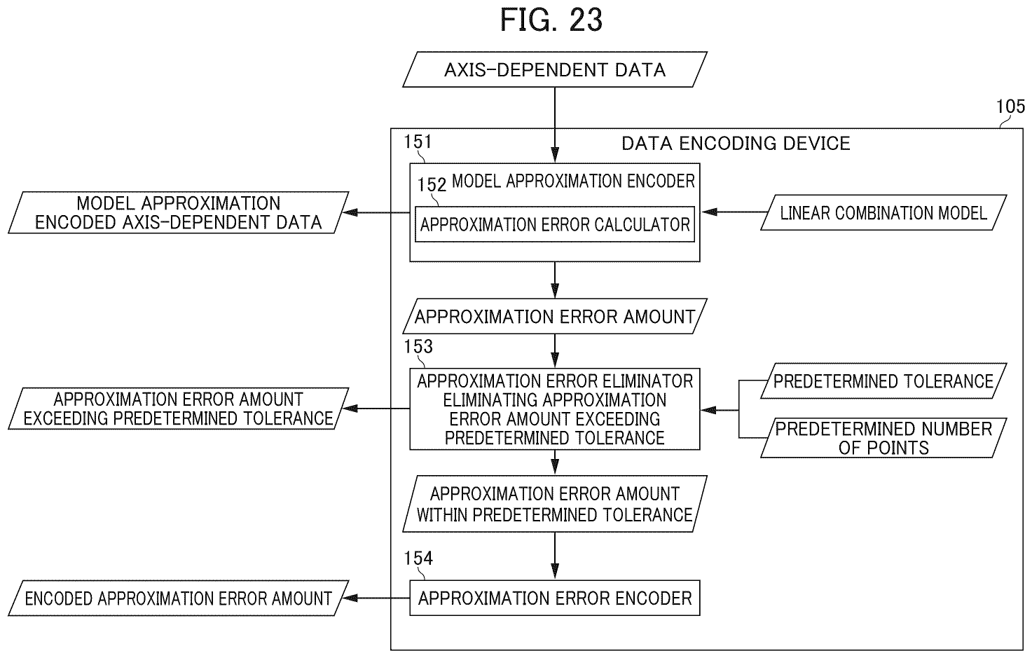

FIG. 23 is a diagram showing a configuration of a fifth example of the data encoding device. As shown in FIG. 23, a data encoding device 105 differs from the data encoding device 104 described above in that the data encoding device 105 further includes an approximation error eliminator 153 that eliminates an approximation error amount equal to or greater than a predetermined tolerance. In addition, an approximation error encoder 154 differs from the above-described approximation error encoder 143 in that the approximation error encoder 154 encodes an approximation error amount within a predetermined tolerance. The configurations other than these differences are the same as those of the fourth example.

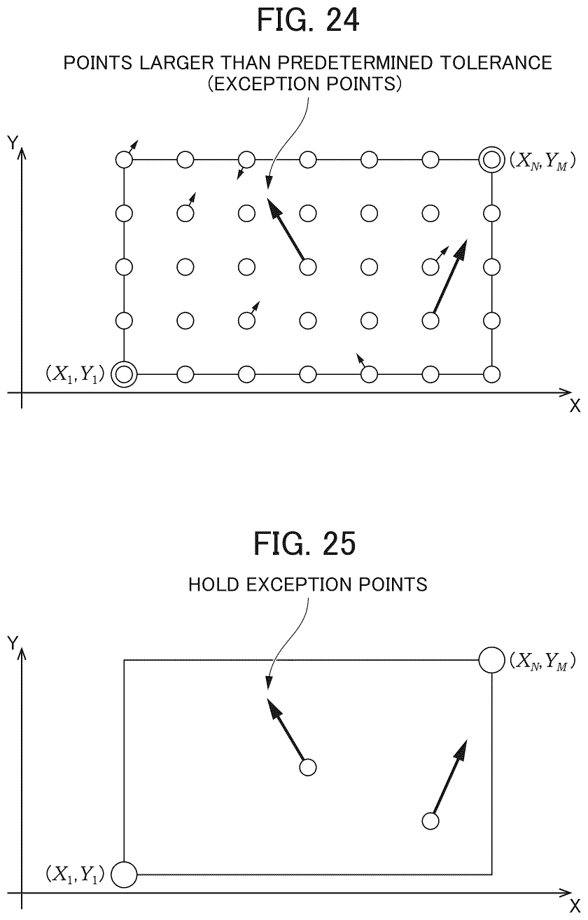

The approximation error eliminator 153 generates an approximation error amount within a predetermined tolerance by eliminating the approximation error amount exceeding a predetermined tolerance from the approximation error amount. Here, FIG. 24 is a diagram showing approximation errors (vectors γ[X] [Y]), each including an exception point larger than a predetermined tolerance. As shown in FIG. 24, the approximation errors (vectors γ[X] [Y]), which are each a difference between an original error amount before model approximation encoding and an error amount after model approximation encoding, may include an exception point larger than a predetermined tolerance. In the present embodiment, the exception points are eliminated by the approximation error eliminator 153.

FIG. 25 is a diagram showing exception points that are excluded and held because the approximation errors (vectors Y [X] [Y]) are larger than a predetermined tolerance. As described above, the approximation error eliminator 153 may separately hold each of the exception points in which the approximation error is larger than a predetermined tolerance, that is, the approximation error amount exceeding a predetermined tolerance, which is eliminated from the approximation error amount. As a result, the axis-dependent data such as the original error amount can be compressed and reproduced without loss.

Examples of the predetermined tolerance include an approximation error allowable value and a predetermined number of points (allowable number of points) of data exceeding the approximation error allowable value. In this case, the approximation error eliminator 153 excludes a point exceeding a preset approximation error allowable value or a predetermined number of points among points exceeding the approximation error allowable value from the approximation errors (vectors γ[X] [Y]). The predetermined tolerance may include 0.

The approximation error encoder 154 encodes an approximation error amount within a predetermined tolerance to generate an encoded approximation error amount. That is, when encoding the approximation errors (vectors γ[X¹] . . . [X^{L}]), the approximation error encoder 154 of the present embodiment performs encoding after excluding points at which the approximation error is larger than a predetermined tolerance.

The approximation error after excluding the points larger than the predetermined tolerance from the approximation error amount, that is, the approximation error amount within the predetermined tolerance, becomes more biased in value and the information entropy becomes smaller, so that the data compression effect is further enhanced by encoding. In addition, for example, the data size after encoding can be further reduced by holding the approximation error amount only at points at which the approximation error is larger than a predetermined tolerance and not holding the other approximation error amounts. Even in this case, it is possible to ensure that the entire approximation error falls within the tolerance.

As described above, according to the data encoding device 105, it is possible to encode and compress the axis-dependent data, which has been conventionally difficult to compress, and it is also possible to achieve the compression with loss within the range of the allowable amount of loss (the predetermined tolerance and the predetermined number of points) by encoding the approximation error amount after the elimination of the approximation error amount exceeding the predetermined tolerance, and in this case, it is possible to reduce the data size compared to the compression without loss.

### SIXTH EXAMPLE

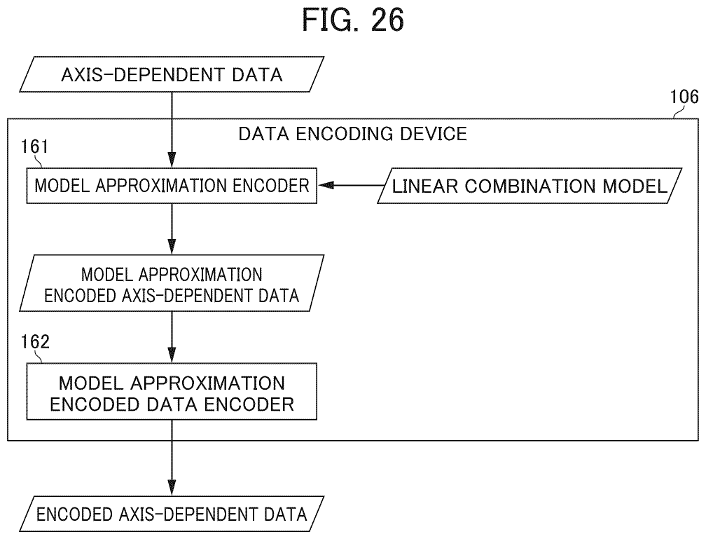

FIG. 26 is a diagram showing a configuration of a sixth example of the data encoding device. As shown in FIG. 26, a data encoding device 106 differs from the data encoding device 101 described above in that the data encoding device 106 further includes a model approximation encoded data encoder 162. The configurations other than this difference are the same as those of the first example.

The model approximation encoded data encoder 162 encodes model approximation encoded axis-dependent data. That is, the model approximation encoded data encoder 162 performs re-encoding of the axis-dependent data after model approximation encoding.

As described in the above-mentioned first example, when the error amount is expressed by the approximation model (vector Ea[X¹] . . . [X^{L}]) as the linear combination model represented by Expression (5), the data can be further compressed by performing encoding on each of the vectors Ea_{X}¹[X¹]. At this time, since the vector Ea_{X}¹[X¹] represents an error of each axis, the model approximation encoded data encoder 62 executes encoding by entropy encoding such as conventionally known Huffman coding, instead of model approximation by an approximation model (vector Ea[X¹] . . . [X^{L}]) as a linear combination model represented by the above-described Expression (5).

As described above, according to the data encoding device 106, since the model approximation encoded data encoder 162 further encodes the encoded axis-dependent data, it is possible to further reduce the data size.

### SEVENTH EXAMPLE

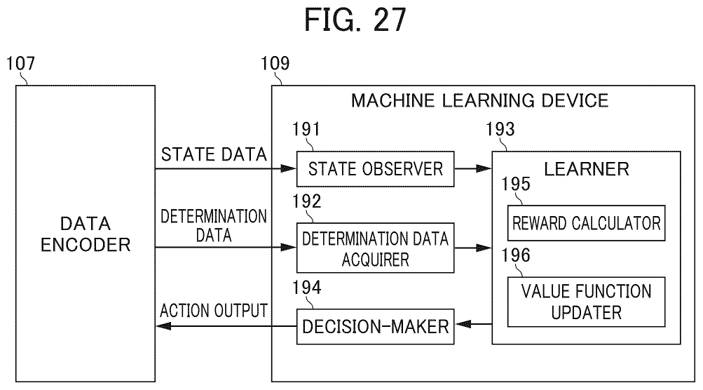

FIG. 27 is a diagram showing a configuration of a seventh example of the data encoding device. As shown in FIG. 27, a data encoding device 107 differs from the data encoding device 103 described above in that the data encoding device 107 includes a learning result acquirer that acquires a reinforcement learning result by a machine learning device 109 instead of the dynamic programming method, and the axis-dependent data is divided into segments using the learning result. The configurations other than this difference are the same as those of the third example.

The machine learning device 109 performs reinforcement learning for optimal division processing of axis-dependent data. In reinforcement learning by the machine learning device 109 according to the present embodiment, when the machine learning device 109 as an agent acquires axis-dependent data such as an error amount of an industrial machine as a state of an environment, and selects divided axis-dependent data as an action, the environment changes based on the action. As the environment changes, the number of points that cannot be approximated and the amount of data after approximation obtained by performing model approximation encoding on the divided axis-dependent data are obtained as determination data. Then, some reward is given according to the obtained determination data, and the machine learning device 109 as an agent selects a better action, i.e., learns the divided axis-dependent data optimal for decision making. The machine learning device 109 as an agent learns to select an action that maximizes the sum of rewards in the future.

Any learning method can be used for reinforcement learning. For example, Q learning, which is a method of learning a value Q (s, a) for selecting a certain action a under a certain state s of a certain environment, can be used. In the Q learning, in a certain state s, an action a having the highest value Q (s, a) is selected as an optimal action from among possible actions a. However, the correct value of the value Q (s, a) is not known at all for the combination of the state s and the action a at the time when the Q learning is started first. Therefore, the machine learning device 109 as an agent selects various actions a under a certain state s, and learns a correct value Q (s, a) by selecting a better action based on a reward given to the action a at that time.

In addition, in order to maximize the sum of rewards obtained in the future, the machine learning device 109 aims to finally obtain Q (s, a)=E[Σ(γ^{t})r^{t}]. Here, E[ ] represents an expected value, t is a time, γ is a parameter of a discount rate to be described later, rₜ is a reward at the time t, and Σ is a total at the time t. The expected value in this expression is an expected value when the state is changed according to the optimal action. However, since it is unknown what the optimal action is in the process of Q-learning, reinforcement learning is performed while searching for various actions. Such an update expression of the value Q (s, a) can be expressed by, for example, the following Expression (11).

$$[ Expression 11 ]$$

$$Q ( {s}_{t + 1} , {a}_{t + 1} ) ← Q ( {s}_{t} , {a}_{t} ) + α ( {r}_{t + 1} + γ {max}_{α} Q ( {s}_{t + 1} , a ) - Q ( {s}_{t} , {a}_{t} ) ) \qquad Expression ( 11 )$$

In Expression (11), sₜ represents the state of the environment at time t, and aₜ represents the action at time t. The state is changed to sₜ₊₁ by the action at. The term rₜ₊₁ represents a reward obtained by a change in the state. The term with max is obtained by multiplying, by γ, the Q value in a case where the action a having the highest Q value known at that time is selected under the state sₜ₊₁. Here, γ is a parameter of 0<γ≤1, and is referred to as a discount rate. Further, α is a learning coefficient, and is in a range of 0≤α≤1.

Expression (11) above represents a method of updating the value Q (sₜ, aₜ) of the action aₜ in the state sₜ based on the reward rₜ₊₁ returned as a result of the trial aₜ. This update expression indicates that, if the value maxₐ Q (sₜ₊₁, a) of the best action in the next state sₜ₊₁ by the action at is larger than the value Q (sₜ, aₜ) of the action at in the state sₜ, Q(sₜ, aₜ) is increased, and if it is smaller, Q(sₜ, aₜ) is decreased. That is, the value of a certain action in a certain state is made closer to the value of the best action in the next state. However, although the difference varies depending on the discount rate γ and the reward rₜ₊₁, basically, the value of the best action in a certain state propagates to the value of the action in the immediately preceding state.

Here, in the Q learning, there is a method of creating a table of Q (s, a) for all the state action pairs (s, a) and performing learning. However, there is a case where the number of states is too large to obtain the values of Q (s, a) of all the state action pairs, and it would take a long time for the Q learning to converge.

Therefore, a known technique called Deep Q-Network (DQN) may be used. Specifically, the value function Q may be configured using an appropriate neural network, parameters of the neural network may be adjusted, and the value function Q may be approximated with an appropriate neural network, such that the value of the value Q (s, a) is calculated. By using the DON, it is possible to shorten the time required for the Q-learning to converge. The DON is described in detail in, for example, the Non-patent Document of “Human-level control through deep reinforcement learning”, Volodymyr Mnih1, [online], [searched on Jan. 17, 2017], the Internet <URL: http://files.davidqiu.com/research/nature14236.pdf>.

Therefore, in order to execute the reinforcement learning described above, the machine learning device 109 includes a state observer 191, a determination data acquirer 192, a learner 193, and a decision-maker 194, as shown in FIG. 27. The learner 193 includes a reward calculator 195 and a value function updater 196.

The state observer 191 acquires axis-dependent data as state data from the data encoding device 107. In addition, the state observer 191 outputs the acquired axis-dependent data to the learner 193.

The determination data acquirer 192 acquires, as determination data from the data encoding device 107, the number of points that cannot be approximated and the approximated data amount obtained by performing model approximation encoding on the divided axis-dependent data. The divided axis-dependent data is obtained by dividing the axis-dependent data into predetermined designated sections in accordance with a predetermined division criterion stored in advance. In addition, the determination data acquirer 192 outputs the acquired number of points that cannot be approximated and the approximated data amount to the learner 193.

The reward calculator 195 of the learner 193 calculates a reward based on the acquired axis-dependent data, the number of points that cannot be approximated and the approximated data amount. Specifically, the reward calculator 195 increases the reward when the number of points that cannot be approximated decreases, and decreases the reward when the number of points that cannot be approximated increases. In addition, the reward calculator 195 increases the reward when the approximated data amount decreases, and decreases the reward when the approximated data amount increases.

The value function updater 196 of the learner 193 updates the stored value function by performing the above-described Q learning based on the axis-dependent data as the state data, the number of points that cannot be approximated and the approximated data amount obtained by performing the model approximation encoding on the divided axis-dependent data as the determination data, and the value of the reward. In addition, the value function stored in the value function updater 196 can be shared by a plurality of machine learning devices communicably connected to each other, for example.

The decision-maker 194 acquires the updated value function from the value function updater 196. In addition, the decision-maker 194 outputs the optimal divided axis-dependent data as an action output to the data encoding device 107 based on the acquired value function.

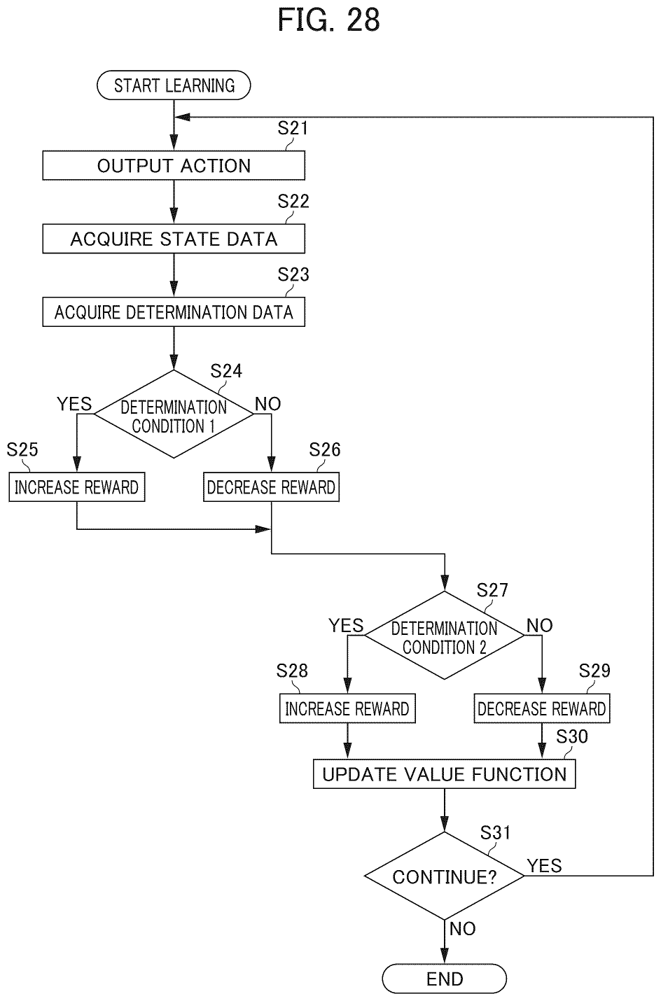

FIG. 28 is a flowchart showing a procedure of learning processing by the machine learning device 109.

In Step S21, first, the machine learning device 109 outputs the divided axis-dependent data as an action output to the data encoding device 107. The divided axis-dependent data outputted in this step is obtained by dividing the axis-dependent data into predetermined designated sections in accordance with a predetermined division criterion stored in advance. The data encoding device 107 performs model approximation encoding on the divided axis-dependent data to generate the number of points that cannot be approximated and the approximated data amount. Thereafter, the processing proceeds to Step S22.

In Step S22, the machine learning device 109 acquires axis-dependent data as state data from the data encoding device 107. Thereafter, the processing proceeds to Step S23.

In Step S23, the machine learning device 109 acquires, as determination data from the data encoding device 107, the number of points that cannot be approximated and the approximated data amount after model approximation encoding of the divided axis-dependent data generated in Step S21. Thereafter, the processing proceeds to Step S24.

In Step S24, as a determination condition 1, it is determined whether the number of points that cannot be approximated when the data encoding device 107 performs model approximation encoding on the divided axis-dependent data has decreased. If it is determined as YES, the processing proceeds to Step S25, where the reward is increased. On the other hand, if it is determined as NO, the processing proceeds to Step S26, where the reward is reduced. Thereafter, the processing proceeds to Step S27.

In Step S27, as a determination condition 2, it is determined whether the amount of data after the model approximation encoding when the model approximation encoding is performed on the divided axis-dependent data by the data encoding device 107 is decreased. If it is determined as YES, the processing proceeds to Step S28, where the reward is increased. On the other hand, if it is determined as NO, the processing proceeds to Step S29, where the reward is decreased. Thereafter, the processing proceeds to Step S30.

In Step S30, the value function stored in the value function updater 196 is updated. Specifically, the value function updater 196 updates the stored value function by performing the above-described Q-learning based on the axis-dependent data as the state data, the number of points that cannot be approximated and the approximated data amount obtained by performing the model approximation encoding on the divided axis-dependent data as the determination data, and the value of the reward. Thereafter, the processing proceeds to Step S31.

In Step S31, it is determined whether to continue the present learning process. If it is determined as YES, the processing returns to Step S21. On the other hand, if it is determined as NO, the present processing is ended.

As described above, according to the data encoding device 107, since the axis-dependent data can be divided into the optimal divided axis-dependent data that can be compressed while reducing the number of data by the reinforcement learning by the machine learning device 109, it is possible to generate an optimal plurality of regions that can be regarded as the linear combination of data of each axis (each axis error), and by performing the model approximation encoding of the linear combination model for each region, it is possible to further compress the axis-dependent data, which has conventionally been difficult to compress.

In each example of the data encoding device described above, a data encoding program for causing each data encoding device to execute each of pieces of processing may be provided. That is, as the first data encoding program, it is possible to provide a data encoding program for causing a computer to execute a model approximation encoding step of generating encoded axis-dependent data obtained by encoding axis-dependent data based on a portion of axis-dependent data depending on coordinate values of each axis of an industrial machine and a linear combination model approximating the axis-dependent data as a linear combination of data of each axis of the industrial machine.

Further, it is possible to provide a second data encoding program further including an axis-dependent data dividing step of dividing the axis-dependent data to generate a plurality of divided axis-dependent data in the first data encoding program, in which the model approximation encoding step generates the encoded axis-dependent data based on the plurality of divided axis-dependent data and the linear combination model.

Further, it is possible to provide a third data encoding program that further includes a dynamic programming processing step of generating the optimal encoded axis-dependent data by executing the dynamic programming method in the second data encoding program, and that causes a computer to execute an optimality evaluating step of evaluating the optimality of the encoded axis-dependent data, a partial dividing step of dividing the axis-dependent data into a plurality of portions to generate partial axis-dependent data, and an optimization result combining step of generating optimal divided axis-dependent data by expanding and combining the partial axis-dependent data.

Further, it is possible to provide a fourth data encoding program for causing a computer to execute the step of generating the optimal divided axis-dependent data based on the reinforcement learning result by the machine learning device in the second data encoding program.

Further, it is possible to provide a fifth data encoding program for causing a computer to execute an approximation error calculation step of calculating an approximation error amount and a step of encoding the approximation error amount to generate an encoded approximation error amount in the first to fourth data encoding programs.

Further, it is possible to provide a sixth data encoding program for causing a computer to execute a step of generating an approximation error amount within a predetermined tolerance by eliminating an approximation error amount exceeding the predetermined tolerance from the approximation error amount, and a step of generating an encoded approximation error amount by encoding the approximation error amount within the predetermined tolerance in the fifth data encoding program.

It is also possible to provide a seventh data encoding program for causing a computer to execute a step of encoding the encoded axis-dependent data in the first to sixth data encoding programs.

In the fourth example described above, the model approximation encoder 141 is configured to include the approximation error calculator 142. However, for example, it may be configured to combine, by the data decoding device, the model approximation encoded axis-dependent data encoded by the data encoding device 104 and calculate the approximation error amount by the difference between the decoded axis-dependent data and the original axis-dependent data.

In addition, in the fourth example described above, the configuration including the approximation error calculator 142 is applied to the first example. However, the present invention is not limited thereto, and such a configuration may be applied to the second example or the third example. Further, in the above-described sixth example, the configuration including the model approximation encoded data encoder 162 is applied to the first example. However, the present invention is not limited thereto, and such a configuration can be applied to other examples. As described above, the above-described examples can be appropriately combined as long as their functions are not impaired.

In the seventh example described above, the machine learning device 109 is provided separately from the data encoding device 107. However, the present invention is not limited thereto, and a machine learning device may be provided inside the data encoding device 107.

### <Data Decoding Device>

Referring back to FIG. 1, the data decoding device 1 according to the first embodiment will be described.

As shown in FIG. 1, the data decoding device 1 includes the decoder 11. The decoder 11 generates model approximation decoded axis-dependent data as decoded axis-dependent data based on the model approximation encoded axis-dependent data and the linear combination model.

Similar to each of the above-described data encoding devices, the data decoding device 1 is configured by using, for example, a computer including memory such as ROM (read only memory) or RAM (random access memory), a CPU (control processing unit), an operation unit such as a keyboard, a display, and a communication control unit, which are connected to each other via a bus. The functions and operations of the functional units described later are achieved by cooperation of a CPU and memory, which are mounted on the computer, and a control program stored in the memory.

The data decoding device 1 may be provided in, for example, a numerical control device (CNC: Computerized Numerical Control) or a robot control device corresponding to a control device of a machine tool or an industrial machine such as a robot. Alternatively, the data decoding device 1 may be provided in an external computer or the like so as to be able to communicate with these control devices.

The decoder 11 acquires, as input data, model approximation encoded axis-dependent data by a linear combination of data of each axis. The model approximation encoded axis-dependent data is generated by each of the above-described data encoding devices. As described above, assuming that the target axis number is defined as L and the L number of target axis names are respectively defined as X¹ to XL, the model approximation encoded axis-dependent data include information of the constant vector c represented by the above-described Expression (7), the vectors Ea_{X}¹[X¹] to Ea_{X}^{L}[X^{L}] which are the L number of pieces of data of each axis (each axis error), and the element numbers N_{X}¹ to N_{X}^{L} of the L number of pieces of data of each axis. Here, it is assumed that data of each axis (each axis error) is obtained by arranging vectors according to the number of elements as represented by the following Expression (12).

$$[ Expression 12 ]$$

$$\vec{{Ea}_{{X}^{l}}} [ {X}^{l} ] = \{ \vec{{v}_{1}} , \vec{{v}_{2}} , … , \vec{{u}_{{N}_{{X}^{l}}}} \} \qquad Expression ( 12 )$$

The linear combination model is stored in, for example, the storage of the data decoding device 1, and is expressed by the following Expression (5). Since the model approximation encoded axis-dependent data conforms to the linear combination model, the decoder 11 calculates vectors Ea[X¹] . . . [X^{L}] as the model approximation decoded axis-dependent data by the linear combination expression represented by Expression (5).

$$[ Expression 13 ]$$

$$\vec{Ea} [ {X}^{1} ] … [ {X}^{L} ] := {{\sum }^{L}}_{l = 1} \vec{{Ea}_{{X}^{l}}} [ {X}^{l} ] + \vec{c} \qquad Expression ( 5 )$$

The decoding by the data decoding device 1 will be described in more detail with reference to a specific example. For example, it is assumed that the number of target axes is two and the two target axis names are X and Y, respectively. At this time, the constant vector c, the vector Ea_{X}[X] and the vector Ea_{Y} [Y] as the two pieces of data of each axis (each axis error), and the respective numbers of elements N_{X} and N_{Y} are inputted to the above Expression (5). For example, an example of the vector Ea_{X} [X] and the vector Ea_{Y} [Y] as data of each axis (each axis error) when N_{X}⁼⁴ and N_{Y}=3 is expressed by the following Expression (13) and Expression (14), respectively.

$$[ Expression 14 ]$$

$$\vec{{Ea}_{X}} [ X ] = \{ \vec{{u}_{1}} , \vec{{u}_{2}} , \vec{{u}_{3}} , \vec{{u}_{4}} \} \qquad Expression ( 13 )$$

$$[ Expression 15 ]$$

$$\vec{{Ea}_{Y}} [ Y ] = \{ \vec{{v}_{1}} , \vec{{v}_{2}} , \vec{{v}_{3}} \} \qquad Expression ( 14 )$$

At this time, the vector Ea[X] [Y] as the model approximation decoded axis-dependent data is expressed by the following Expression (15).

$$[ Expression 16 ]$$

$$\vec{Ea} [ X ] [ Y ] := \vec{{Ea}_{X}} [ X ] + \vec{{Ea}_{Y}} [ Y ] + \vec{c} \qquad Expression ( 15 )$$

Therefore, for example, in a case of the vector Ea[3] [1], since the vector Ea_{X} [3]=vector u₃ and the vector Ea_{Y} [1]=vector vi, the vector Ea[3] [1] is expressed by the following Expression (16).

$$[ Expression 17 ]$$

$$\vec{Ea} [ 3 ] [ 1 ] := \vec{{u}_{3}} + \vec{{v}_{1}} + \vec{c} \qquad Expression ( 16 )$$

According to the present embodiment, the following advantageous effects are achieved.

The data decoding device 1 according to the present embodiment includes the decoder 11 that generates model approximation decoded axis-dependent data obtained by decoding model approximation encoded axis-dependent data based on a linear combination model that approximates axis-dependent data depending on coordinate values of each axis of an industrial machine as a linear combination of data of each axis of the industrial machine and model approximation encoded axis-dependent data that is model-approximated by the linear combination model. With such a configuration, it is possible to decode the encoded axis-dependent data obtained by encoding the axis-dependent data depending on the coordinate values of each axis of the industrial machine. Further, it is possible to increase data such as the error amount that can be used by being inputted to the control device or the like of the industrial machine without increasing the storage capacity, and it is possible to compensate the error of the industrial machine with higher accuracy.

### SECOND EMBODIMENT

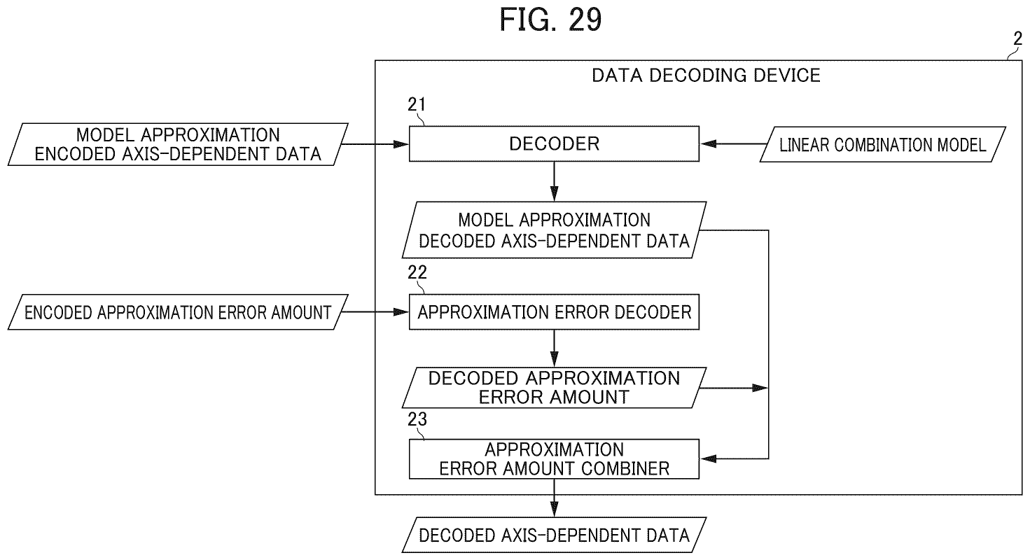

FIG. 29 is a diagram showing a configuration of a data decoding device according to the second embodiment. As shown in FIG. 29, a data decoding device 2 according to the second embodiment differs from the data decoding device 1 according to the first embodiment in that the data decoding device 2 includes an approximation error decoder 22 and an approximation error amount combiner 23. Further, the second embodiment differs from the first embodiment in that the decoded axis-dependent data is generated by combining the decoded approximation error amount with the model approximation decoded axis-dependent data generated by the decoder 21. The configurations other than these differences are the same as those of the first embodiment.

The approximation error decoder 22 acquires the encoded approximation error amount obtained by encoding the approximation error amount obtained when the axis-dependent data is model-approximated by the linear combination model. Further, the approximation error decoder 22 also decodes the acquired encoded approximation error amount to generate a decoded approximation error amount. The encoded approximation error amount is generated by encoding the approximation error amount by the approximation error encoder 43 in the data encoding device 104 of the fourth example described above.

The approximation error amount combiner 23 acquires the model approximation decoded axis-dependent data generated by the decoder 21 and the decoded approximation error amount generated by the approximation error decoder 22. Further, the approximation error amount combiner 23 combines the acquired model approximation decoded axis-dependent data with the acquired decoded approximation error amount to generate decoded axis-dependent data after the approximation error amount combination. Here, the combining method is not particularly limited. For example, the combining method may be adding. The approximation error amount combiner 23 can generate the decoded axis-dependent data after the approximation error amount combination by adding the decoded approximation error amount to the model approximation decoded axis-dependent data.

According to the present embodiment, the following advantageous effects are achieved.

The data decoding device 2 according to the present embodiment includes the approximation error decoder 22 that acquires the encoded approximation error amount obtained by encoding the approximation error amount obtained when the axis-dependent data is model-approximated by the linear combination model, and decodes the encoded approximation error amount to generate the decoded approximation error amount. Further, the data decoding device 2 according to the present embodiment includes the approximation error amount combiner 23 that combines the model approximation decoded axis-dependent data with the decoded approximation error amounts to generate the decoded axis-dependent data after the approximation error amount combination. With such a configuration, according to the present embodiment, since the encoded axis-dependent data can be decoded and the encoded approximation error amounts can be decoded and combined, for example, as long as the approximation error amount exceeding the predetermined tolerance is not eliminated from the encoded approximation error amount, it is possible to reproduce the axis-dependent data such as the original error amount without loss.

In the present embodiment, the decoded approximation error amount is generated by the approximation error decoder 22. However, instead of the decoded approximation error amount, an approximation error amount generated by model approximation encoding of the axis-dependent data by the above-described data encoding device may be used. In this case, the approximation error decoder 22 is not necessary. With such a configuration, the decoded axis-dependent data matches the axis-dependent data before the model approximation encoding. That is, it is possible for the data decoding device 2 of the present embodiment to decode the original axis-dependent data without loss.

### THIRD EMBODIMENT

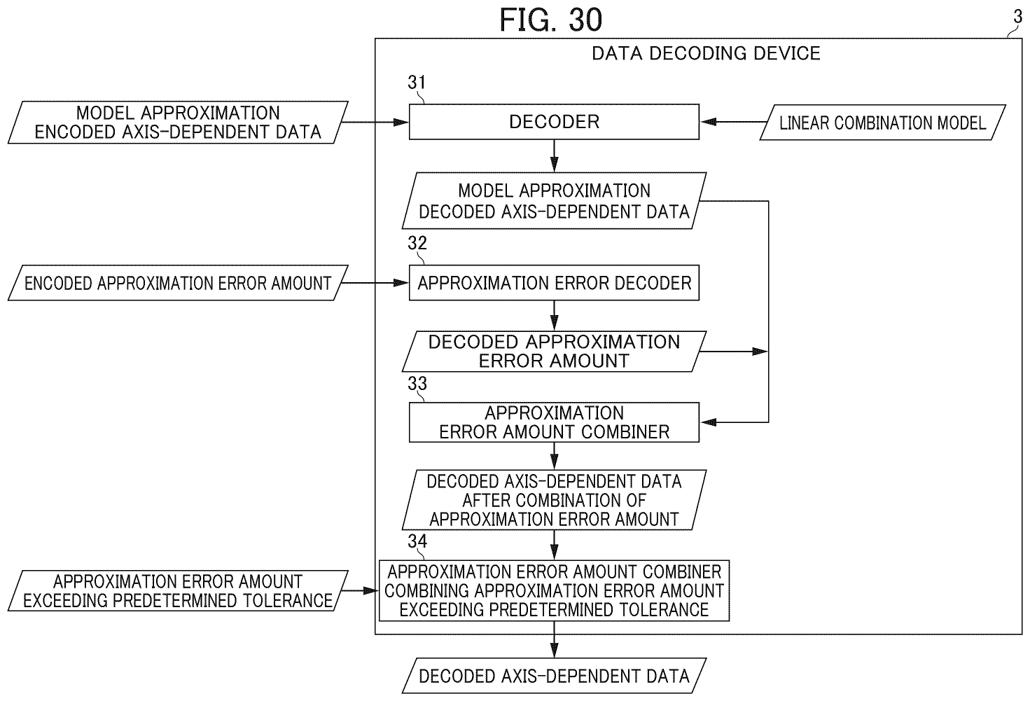

FIG. 30 is a diagram showing a configuration of a data decoding device according to a third embodiment. As shown in FIG. 30, a data decoding device 3 according to the third embodiment differs from the data decoding device 2 according to the second embodiment in that the data decoding device 3 includes an approximation error amount combiner 34 that combines approximation error amounts exceeding a predetermined tolerance. The third embodiment differs from the second embodiment in that the decoded axis-dependent data is generated by combining the approximation error amounts exceeding a predetermined tolerance with the decoded axis-dependent data after the approximation error amount combination. The configurations other than these differences are the same as those of the second embodiment.

Here, the encoded approximation error amounts to be combined by the approximation error decoder 32 of the present embodiment are generated by encoding the approximation error amounts within a predetermined tolerance by the approximation error encoder 154 in the data encoding device 105 of the above-described fifth example. That is, the approximation error amount used in the present embodiment is an approximation error amount within a predetermined tolerance from which the approximation error amount exceeding the predetermined tolerance is eliminated.

The approximation error amount combiner 34 that combines approximation error amounts exceeding the predetermined tolerance acquires the approximation error amounts exceeding the predetermined tolerance, and combines the decoded axis-dependent data after the approximation error amount combination with the approximation error amounts exceeding the predetermined tolerance to generate the decoded axis-dependent data. Here, the combining method is not particularly limited. For example, the combining method may be adding. The approximation error amount combiner 34 that combines approximation error amounts exceeding the predetermined tolerance can generate the decoded axis-dependent data by adding the approximation error amount exceeding the predetermined tolerance to the decoded axis-dependent data after the approximation error amount combination.

The approximation error amount exceeding the predetermined tolerance is generated by the approximation error eliminator 153 that eliminates the approximation error amount exceeding the predetermined tolerance in the data encoding device 105 of the above-described fifth example. That is, the approximation error amount exceeding the predetermined tolerance generated by subtracting the approximation error amount within the predetermined tolerance from the approximation error amount by the approximation error eliminator 153 is used in the approximation error amount combiner 34 that combines approximation error amounts exceeding the predetermined tolerance of the present embodiment.

According to the present embodiment, the following advantageous effects are achieved.

In the data decoding device 3 according to the present embodiment, the approximation error amount is set to an approximation error amount within a predetermined tolerance from which the approximation error amount exceeding the predetermined tolerance is eliminated. In addition, the data decoding device 3 according to the present embodiment includes the approximation error amount combiner that combines approximation error amounts exceeding a predetermined tolerance. The approximation error amount combiner acquires an approximation error amount exceeding a predetermined tolerance and generates decoded axis-dependent data by combining the approximation error amounts exceeding the predetermined tolerance with the decoded axis-dependent data after the approximation error amount combination. With such a configuration, according to the present embodiment, the encoded axis-dependent data can be decoded, and the encoded approximation error amounts can be decoded and combined, and the approximation error amounts exceeding the predetermined tolerance can also be combined, such that it is possible to reproduce the axis-dependent data such as the original error amounts without loss.

### FOURTH EMBODIMENT

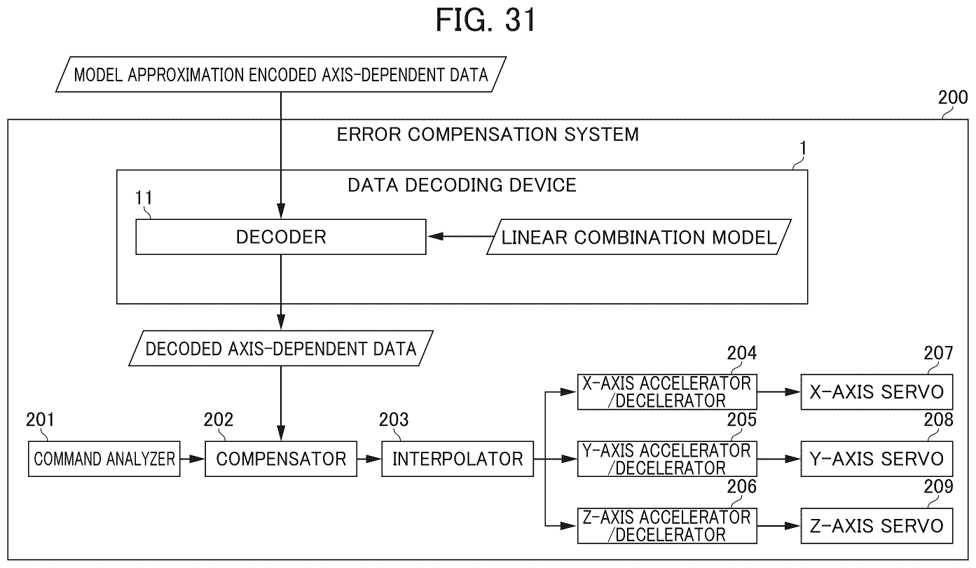

FIG. 31 is a diagram showing a configuration of an error compensation system 200 including the data decoding device 1 according to the first embodiment. The error compensation system 200 according to the present embodiment compensates for an error of an industrial machine using decoded axis-dependent data generated by the data decoding device 1.

The error compensation system 200 is configured using, for example, a computer including memory such as ROM (read only memory) or RAM (random access memory), a CPU (control processing unit), an operation unit such as a keyboard, a display, and a communication control unit, which are connected to each other via a bus. The functions and operations of the functional units described later are achieved by the cooperation of a CPU and memory, which are mounted on the computer, and a control program stored in the memory.

The error compensation system 200 may be provided in, for example, a numerical control device (CNC: Computerized Numerical Control) or a robot control device corresponding to a control device of a machine tool or an industrial machine such as a robot. Alternatively, the error compensation system 200 may be provided in an external computer or the like so as to be able to communicate with these control devices.

As shown in FIG. 31, the error compensation system 200 includes the data decoding device 1, a command analyzer 201, a compensator 202, an interpolator 203, an X-axis accelerator/decelerator 204, a Y-axis accelerator/decelerator 205, a Z-axis accelerator/decelerator 206, an X-axis servo 207, a Y-axis servo 208, and a Z-axis servo 209. The details of the data decoding device 1 are as described above.

The command analyzer 201 reads and analyzes a machining program for each block, and generates movement command data for commanding movement of each control axis of a machine tool or the like based on the analysis result. The command analyzer 201 transmits the generated movement command data to the compensator 202 described later.

The compensator 202 compensates for the movement command data acquired from the command analyzer 201 based on the decoded axis-dependent data generated by the data decoding device 1. The compensation processing by the compensator 202 will be described in detail later.

The interpolator 203 generates interpolation data by performing interpolation calculation on points on the command path in a predetermined interpolation cycle based on the movement command data generated from the command analyzer 201 and compensated by the compensator 202. The interpolator 203 distributes and transmits the generated interpolation data to the X-axis accelerator/decelerator 204, the Y-axis accelerator/decelerator 205, and the Z-axis accelerator/decelerator 206, which will be described later.

The X-axis accelerator/decelerator 204, the Y-axis accelerator/decelerator 205, and the Z-axis accelerator/decelerator 206 respectively generate pulse signals of the X-axis servo, the Y-axis servo, and the Z-axis servo based on each piece of the interpolation data transmitted from the interpolator 203, for each interpolation cycle. The X-axis accelerator/decelerator 204, the Y-axis accelerator/decelerator 205, and the Z-axis accelerator/decelerator 206 respectively input the generated pulse signals to the X-axis servo, the Y-axis servo, and the Z-axis servo, thereby moving a plurality of mechanical elements of the machine tool along the plurality of control axes.

Next, compensation processing by the compensator 202 will be described in detail. First, the error compensation system 200 acquires model approximation encoded axis-dependent data as input data. The decoder 11 of the data decoding device 1 generates vectors Ea[X¹] . . . [X^{L}], which are model approximation decoded axis-dependent data as decoded axis-dependent data, based on the acquired model approximation encoded axis-dependent data and the linear combination model.

As shown in FIG. 31, when the error compensation system 200 includes, for example, three axes of X, Y, and Z, the data decoding device 1 generates a vector Ea[X] [Y] [Z] as decoded axis-dependent data. Here, it is assumed that X, Y, and Z in the vector Ea[X] [Y] [Z] are indexes obtained by quantizing the coordinate values of the axes X, Y, and Z included in the error compensation system 200 by the compensation point intervals Δ_{X}, Δ_{Y}, and Δ_{Z} of the axes.

A specific example will be described. For example, when the coordinate values of the axes are (X, Y, Z)=(100.0, 40.0, 30.0) and the compensation point intervals of the axes are (Δ_{X}, Δ_{Y}, Δ_{Z})=(25.0, 20.0, 30.0), the quantized results of the coordinate values of the axes are (100.0/25.0, 40.0/20.0, 30.0/30.0)=(4, 2, 1). Therefore, the vector Ea[4] [2] [1] as the decoded axis-dependent data can be regarded as an error amount at each axis coordinate value (X, Y, Z)=(100.0, 40.0, 30.0), and error compensation can be executed.

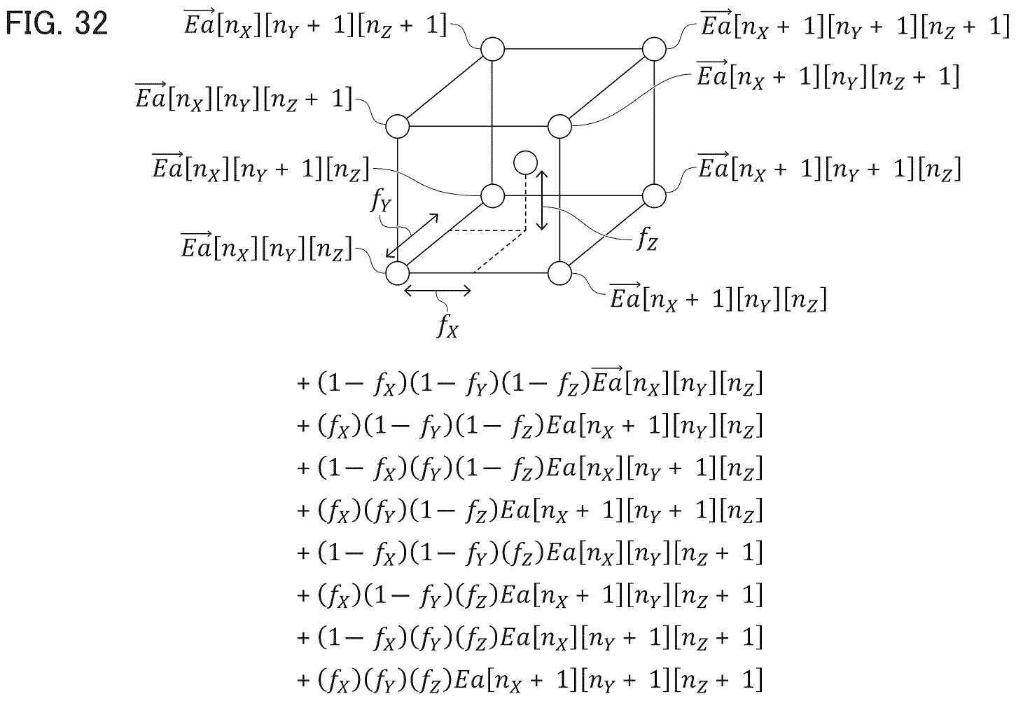

Error compensation in a case where the value after quantization is not an integer such as (4, 2, 1) and has a fraction to the decimal point will be described with reference to FIG. 32. FIG. 32 is a diagram for explaining error compensation by the compensator 202, and more specifically, a diagram for explaining error compensation in a case where a value after quantization has a fraction after the decimal point. Here, for example, it is assumed that the quantization result is (n_{X}+f_{X}, n_{Y}+f_{Y}, n_{Z}+f_{Z}). Herein, n_{X}, n_{Y}, and n_{Z} are integer values, and f_{X}, f_{Y}, and f_{Z} are decimal values greater than or equal to 0 and less than 1.

As shown in FIG. 32, the decoded axis-dependent data of one of the eight vertices of the cube is represented by a vector Ea[n_{X}] [n_{Y}] [n_{Z}], and the decoded axis-dependent data of each of the remaining seven vertices is represented by a vector Ea[n_{X}⁺¹] [n_{Y}] [n_{Z}], a vector Ea[n_{X}⁺¹] [n_{Y}+1] [n_{Z}], a vector Ea[n_{X}⁺¹] [n_{Y}] [n_{Z}+1], a vector Ea[n_{X}⁺¹] [n_{Y}+1] [n_{z}+1], and a vector Ea[n_{Y}] [n_{Y}+1] [n_{Z}], a vector Ea[X] [n_{Y}+1] [n_{Z}+1] and a vector Ea[X] [n_{Y}] [n_{Z}+1]. At this time, as shown in FIG. 32, the current coordinate value in the cube is represented by (n_{X}+f_{X}, n_{Y}+f_{Y}, n_{Z}+f_{Z}), and the error compensation can be executed by setting the inner sum calculated by weighted summation of the decoded axis-dependent data of the eight vertices as the decoded axis-dependent data of the current coordinate value, that is, the error amount.

According to the present embodiment, the following advantageous effects are achieved.

The error compensation system 200 according to the present embodiment includes the compensator 202 and the data decoding device 1, and the compensator 202 compensates for the error of the industrial machine based on the decoded axis-dependent data. With such a configuration, according to the present embodiment, it is possible to decode the encoded axis-dependent data obtained by encoding the axis-dependent data depending on the coordinate values of each axis of the industrial machine and, therefore, it is possible to increase data such as the error amount that can be used by being inputted to the control device or the like of the industrial machine without increasing the storage capacity, and it is possible to compensate the error of the industrial machine with higher accuracy.

In each embodiment of the data decoding device described above, a data decoding program for causing each data decoding device to execute each piece of processing may be provided. That is, as the first data decoding program, it is possible to provide a data decoding program for causing a computer to execute a step of generating model approximation decoded axis-dependent data obtained by decoding model approximation encoded axis-dependent data based on a linear combination model that approximates axis-dependent data depending on coordinate values of each axis of an industrial machine as a linear combination of data of each axis of the industrial machine and model approximation encoded axis-dependent data that are model-approximated by the linear combination model.

Further, it is also possible to provide a second data decoding program for causing a computer to execute a step of obtaining an encoded approximation error amount obtained by encoding an approximation error amount obtained when the axis-dependent data is model-approximated by a linear combination model and decoding the encoded approximation error amount to generate a decoded approximation error amount, and a step of combining the decoded approximation error amount with the model approximation decoded axis-dependent data to generate the decoded axis-dependent data after the approximation error amount combination, in the first data decoding program.

Further, it is possible to provide a third data decoding program for causing a computer to execute a step of setting the approximation error amount to an approximation error amount within a predetermined tolerance from which the approximation error amount exceeding the predetermined tolerance is eliminated; acquiring the approximation error amount exceeding the predetermined tolerance; and combining the approximation error amount exceeding the predetermined tolerance with the decoded axis-dependent data after the approximation error amount combination, thereby generating the decoded axis-dependent data, in the second data decoding program.

Further, it is possible to provide an error compensation program for causing the above-described error compensation system 200 to execute the compensation processing, the error compensation program causing a computer to execute a step of compensating for an error of an industrial machine based on decoded axis-dependent data.

In addition, the present disclosure is not limited to the above-described embodiments, and modifications and improvements within a range in which the object of the present disclosure can be achieved are included in the present disclosure.

The fourth embodiment is configured to include the data decoding device 1 according to the first embodiment. However, the present invention is not limited thereto. For example, the fourth embodiment may be configured to include the data decoding device 2 according to the second embodiment or the data decoding device 3 according to the third embodiment.

### EXPLANATION OF REFERENCE NUMERALS

1, 2, 3 data decoding device
11, 21, 31 decoder
22, 32 approximation error decoder
23, 33 approximation error amount combiner
34 approximation error amount combiner combining approximation error amount exceeding predetermined tolerance
101, 102, 103, 104, 105, 106, 107 data encoder
109 machine learning device
111, 121, 131, 141, 151, 161 model approximation encoder
122, 132 axis-dependent data divider
133 dynamic programming processor
134 optimality evaluator after model approximation encoding
135 partial divider of axis-dependent data
136 optimization result combiner of partial axis-dependent data
142 approximation error calculator
143 approximation error encoder
152 approximation error calculator
153 approximation error eliminator eliminating approximation error exceeding the predetermined tolerance
154 approximation error encoder
162 model approximation encoded data encoder
200 error compensation system
201 instruction analyzer
202 compensator
203 interpolator
204 X-axis accelerator/decelerator
205 Y-axis accelerator/decelerator
206 Z-axis accelerator/decelerator
207 X-axis servo
208 Y-axis servo
209 Z-axis servo

1. A data decoding device that decodes encoded data, comprising:
a decoder that generates, based on a linear combination model that approximates axis-dependent data depending on coordinate values of each axis of an industrial machine as a linear combination of data of each axis of the industrial machine, and model approximation encoded axis-dependent data that are model-approximated by the linear combination model, model approximation decoded axis-dependent data obtained by decoding the model approximation encoded axis-dependent data.

2. The data decoding device according to claim 1, further comprising:
an approximation error decoder that acquires an encoded approximation error amount obtained by encoding an approximation error amount obtained when the axis-dependent data is model-approximated by the linear combination model, and decodes the encoded approximation error amount to generate a decoded approximation error amount; and
an approximation error amount combiner that combines the model approximation decoded axis-dependent data with the decoded approximation error amount to generate decoded axis-dependent data after approximation error amount combination.

3. The data decoding device according to claim 2, wherein
the approximation error amount is an approximation error amount within a predetermined tolerance from which an approximation error amount exceeding the predetermined tolerance is eliminated, and
the data decoding device further comprises an approximation error amount combiner that combines approximation error amounts exceeding the predetermined tolerance, the approximation error amount combiner being configured to acquire the approximation error amount exceeding the predetermined tolerance and combine the decoded axis-dependent data after the approximation error amount combination with the approximation error amount exceeding the predetermined tolerance, thereby generating decoded axis-dependent data.

4. An error compensation system that compensates for an error of an industrial machine,
the system comprising a compensator and the data decoding device according to claim 1,
wherein the compensator compensates for the error of the industrial machine based on the decoded axis-dependent data.

5. A non-transitory computer-readable medium storing a data decoding program that decodes encoded data, the non-transitory computer-readable medium storing the program causing a computer to execute:
a step of generating, based on a linear combination model that approximates axis-dependent data depending on coordinate values of each axis of an industrial machine as a linear combination of data of each axis of the industrial machine, and model approximation encoded axis-dependent data that are model-approximated by the linear combination model, model approximation decoded axis-dependent data obtained by decoding the model approximation encoded axis-dependent data.

6. An error compensation system that compensates for an error of an industrial machine,
the system comprising a compensator and the data decoding device according to claim 2,
wherein the compensator compensates for the error of the industrial machine based on the decoded axis-dependent data.

7. An error compensation system that compensates for an error of an industrial machine,
the system comprising a compensator and the data decoding device according to claim 3,
wherein the compensator compensates for the error of the industrial machine based on the decoded axis-dependent data.
